(19) United States
(12) Patent Application Publication
(10) Pub. No.: US 2025/0141394 A1
(43) Pub. Date: May 1, 2025

(54) SOLAR MODULE AND SOLAR MODULE SYSTEM WITH A PLURALITY OF SOLAR MODULES

(71) Applicant: Blue Green Power GmbH, Handeloh (DE)

(72) Inventors: Andre Richter, Handeloh (DE); Andreas Dreisiebner, Handeloh (DE)

(21) Appl. No.: 18/838,641

(22) PCT Filed: Feb. 15, 2023
(86) PCT No.: PCT/EP2023/053793

§ 371 Date: Aug. 15, 2024

(30) Foreign Application Priority Data
Feb. 17, 2022 (WO) PCT/EP2022/054000

(51) Int. Cl. H02S 20/10; H02H 7/20; H02S 40/36; H10F 77/50

(52) U.S. Cl. CPC H02S 20/10; H02H 7/20; H02S 40/36; H10F 77/50

(57) ABSTRACT

A solar module that is operable in the extra-low voltage range and includes at least one photovoltaic cell for converting radiant energy into electrical energy and two planar elements made of plastic that sandwich the at least one photovoltaic cell. The solar module has at least one positive contact element and at least one negative contact element for tapping an electrical output voltage of the solar module. The positive contact element and the negative contact element are arranged at least partially between the two planar elements and each include at least one electrically uninsulated exposed contacting portion. A solar module system includes a plurality of solar modules connected in parallel and a bearing structure which electrically interconnects and supports the plurality of solar modules.

### BACKGROUND OF THE INVENTION

### Field of the Invention

The invention relates to a solar module with at least one photovoltaic cell for converting radiant energy into electrical energy. Furthermore, the invention relates to a solar module system with a plurality of solar modules.

### Description of Related Art

Since the expansion of renewable energies is a central pillar of the energy transition, a large amount of renewable energy must be generated in the future. Wind and solar energy are among the most important renewable energy sources. The use of solar energy or sunlight therefore plays a key role in the expansion of renewable energies. In order to be able to use sunlight, solar module systems must be provided that convert sunlight or solar energy as radiant energy from the sun into electrical energy. Sunlight has a typical energy density of 800 to 2000 kWh/m² and year. Therefore, very large areas are needed in order to generate sufficient energy.

Hence, new places and possibilities for easy use of the sun's radiant energy must be made accessible. This requires, first of all, suitable solar modules and, secondly, a connection of these solar modules to a suitable solar module system.

The solar modules known in the prior art have the disadvantage that they are hardly applicable for simple use. The known solar modules are not very flexible to use and can only be combined to solar module systems with great effort. These known solar modules have an expensive and heavy basic structure, in particular due to the materials used, the insulation used and the moisture protection devices used. This also has a corresponding effect on the solar module systems, in which a large number of known solar modules are typically connected in series in order to be able to use the solar energy with high voltage and low losses. This serial connection requires that the solar modules all face the sun in the same way. This results in an increased planning effort. In addition, the connection of the known solar modules to a solar module system can only be carried out by a specialist. Due to the high weight of the individual solar modules, complex bearing structures are also necessary in order to connect the solar modules securely to form a system.

### SUMMARY OF THE INVENTION

It is therefore an object of the invention to provide a solar module which eliminates the above-mentioned problems and disadvantages of the prior art. In particular, it is the object of the present invention to provide a solar module which includes a simple structure with a low weight and which is further versatile and easy to use and, in particular, can be assembled by persons who are not specialists. Furthermore, it is the object of the invention to provide a corresponding solar module system which also eliminates the above-mentioned problems and disadvantages of the prior art.

The solution according to the invention consists in particular in providing a solar module which can be operated in the extra-low voltage range. In particular, the solar module is limited in such a way that the output voltage is limited to the extra-low voltage range, i.e. in particular below 60V.

The solar module includes at least one photovoltaic cell for converting radiant energy into electrical energy and two planar elements, in particular made of plastic, which enclose the at least one photovoltaic cell in a sandwich-like manner. The solar module includes at least one positive contact element and at least one negative contact element for tapping an electrical output voltage of the solar module. The positive contact element and the negative contact element are arranged at least partially between the two planar elements and each include at least one electrically uninsulated exposed contacting portion. The contacting portion is an integral portion of the contact element. Hence, the contact element and the respective contacting portion preferably are made in one piece.

Preferably, an output voltage limiter is associated with the solar module, wherein the output voltage limiter is adapted to limit the output voltage to an extra-low voltage, in particular below 60V, and/or wherein the number of photovoltaic cells is selected in such a way that the output voltage remains in the extra-low voltage range, in particular below 60V.

The solar module can be operated in the extra-low voltage range (ELV). This means that the output voltage of the solar module always has a voltage value within the extra-low voltage range during operation, storage and transportation. An extra-low voltage is understood to be a voltage that is so low that contact with the conducting parts is possible without injury, in particular according to the applicable legal regulations. In particular, the voltages are so low that neither muscle cramps nor burns occur when coming into contact with the extra-low voltage. Even if the exact extra-low voltage is country-specific, it is generally a part of the low voltage whose values do not exceed 120 V DC.

The use of extra-low voltages has enormous implications for technical implementation: less insulation needs to be used, power can be transferred between solar modules and inverters without any electrical insulation at all, and installation is possible in a do-it-yourself process without having to hire experts. In particular, there is no need to completely insulate the contacting portions. Thus, electrically uninsulated exposed contacting portions are possible, which create a simple connection possibility. By omitting the insulation, the solar modules can also be manufactured with a lower weight. Existing structures can be used directly to conductively connect solar modules: Battens or slats can be easily converted to current-carrying busbars with a conductive tape and used to electrically connect solar modules. This drastically reduces the assembly effort and the overall cost of the system.

In addition, the extra low voltage used is always below the physical limit for electric arcs. The typical limit at sea level is about 350 Vdc for maintaining electric arcs. The ELV, on the other hand, is below 120 V in all cases and typically below 60 V in most cases. This is much less than the minimum voltage to maintain an electric arc.

Electric arcs can cause fires. Conventional solar modules connected in series generate high voltages and are generally at risk of fire. Therefore, they cannot be used in applications with explosive gases or highly flammable materials nearby. Modules limited to ELVs cannot generate electric arcs and have little fire hazard. Thus, the solar modules according to the invention can be used in such fire hazard applications.

Another point is that the solar module can be manufactured much more cost-effectively. Since electric arcs are physically impossible in the solar module due to the extra low voltage, there is no need to pay attention to air bubbles inside the module during the production process. In conventional solar modules, such air bubbles must be carefully prevented, especially adjacent to metallic parts.

Also, by eliminating insulation, solar modules can be manufactured more economically, efficiently and with lower weight.

In addition, the assembly effort is considerably reduced, as no specialist is required for assembly with extra-low voltage. Furthermore, there is no need for special connectors or a junction box to connect the solar module. The elimination of these connectors and the low weight of the solar modules allow easier installation even at greater heights, so that the solar modules can be used in more diverse ways. In addition, degradation factors such as PID (potential induced degradation) are avoided. The low electrical voltage thus increases the service life of the solar modules.

The use of planar elements made of plastic also has several advantages. For example, the use of planar elements made of glass can be dispensed with. Plastic can be configured as an impact-resistant plastic so that there is no risk of injury to bystanders in the event of a collision with an object. In addition, the solar module can be configured with a smaller overall thickness, since the planar elements made of plastic must include a smaller thickness than glass under the same conditions. In addition, avoiding glass further reduces the weight of the solar module. For example, the weight of the solar module can thus be reduced to about 3 kg/m² and preferably between 1.5 to 2.5 kg/m². Furthermore, it is easy to drill and otherwise process the planar elements made of plastic, so that the assembly as a whole can be designed more freely. In addition, it is easier to manufacture different sizes. In the case of solar glass modules, it is difficult to change the size, especially because of the tempered glass. Bending the planar elements enables completely new applications and ways of construction.

Overall, the solar module according to the invention provides a light-weight, simply constructed solar module that can be manufactured inexpensively:

Limiting the voltage in the solar module to ELV is a major aspect of the present invention. Assuming the ELV limit is 60 V: Increasing the voltage from 59.9 V to 60.1 V may not seem like much, but in the technical field of solar systems, it has a dramatic impact on in-field realization:
All electrical surfaces must be protected with adequate insulation;
Higher insulation requirements in the solar module itself;
Double insulated cables and junction boxes;
Bypass diodes and no reverse polarity protection;
Specially designed solar connectors;
Higher requirements for the certification process;
Protection of the solar system by a fence, etc. to prevent access to the system and protect people;
Trained personnel to install and operate the solar system.

Many aspects of the invention raised later are only made possible by the presence of ELV:
ELV reduces the need for insulation and glass, etc. Thus, plastic module with relatively thin plastic sheets as planar elements can be used. This enables low-cost module production and application even where shattering glass would be critical (e.g., agrivoltaics). By manufacturing from plastic, customizable module sizes can be easily achieved because the plastic sheet can be cut to any size during production. Thus, the production of very long, rolled solar modules is also possible.
The contacts, i.e. the contact elements, can be left uninsulated. This eliminates the need for cables and junction boxes.
The cells can be protected with thin plastic material. This enables cost-effective module production.
ELV significantly reduces the risk of fire, enabling applications in fire-prone areas such as industrial production and agriculture (e.g. dust, explosive gases).
Do-it-yourself installation of the solar system is possible.
Fail-safe network of parallel solar modules and inverters are possible.
Easy conversion of wood battens or existing structures into conductive busbars, allowing use of a variety of locally available materials.
Simple mounting structures with insulation using wood and other readily available materials.

According to the invention, the output voltage of the solar module is an extra-low voltage preferably lower than 60 V. Consequently, the term “ELV” can be replaced by “voltages below 60V”.

The solar module preferably includes a nominal voltage of 40 V, 36 V, 24 V or 12 V, particularly preferably of 48 V. The advantage of a 48 V voltage is in particular that it can be used directly for charging batteries without voltage conversion. This makes it easy to store energy. In addition, 12 V, 24 V, 36 V and 48 V technology provides a number of standard components, such as inverters.

According to the invention, an output voltage limiter is associated with the solar module, which is adapted to limit the output voltage to an extra-low voltage or to keep it within the extra-low voltage range. Preferably, the solar module includes the output voltage limiter. Alternatively or cumulatively, the number of photovoltaic cells is selected in such a way that the output voltage remains in the extra-low voltage range during the entire operation or in a specific operating range of the solar module, in particular without additional voltage limitation. The entire operating range can, for example, be a range from 50° C. to −20° C. The specific operating range can represent, for example, a range from 50° C. to 20° C. In this example, an output voltage limiter could then be active in the range of 0° C. to −20° C. not covered by the specific operating range.

When photovoltaic cells are connected in series, the voltages of the photovoltaic cells add up. It is therefore possible to keep the output voltage of the solar module in the extra-low voltage range by limiting the number of photovoltaic cells or solar cells connected in series. For example, the number of series-connected photovoltaic cells is determined as follows: Starting from a photovoltaic cell with an open-circuit voltage of 0.7 V at 25° C. and a temperature coefficient of the open-circuit voltage of −0.35%/° C., the voltage increases by 16% to 0.81 V per photovoltaic cell at a cell temperature of −20° C. If an exemplary extra-low voltage of 60 V is not to be exceeded during operation even at −20° C., only 74 photovoltaic cells could be connected in series without an additional protection circuit including at least the output voltage limiter.

Alternatively, however, it is also possible to use a corresponding protection circuit including at least the output voltage limiter to actively limit the output voltage of the solar module. This has the following advantage: At 25° C., 85 photovoltaic cells would generally be possible under the above assumptions. If the voltage is actively limited by means of the output voltage limiter when the temperature drops below 25° C., all 85 photovoltaic cells can still be used. Furthermore, the maximum power point (MPP), i.e. the point at which the greatest possible power can be extracted from a photovoltaic cell, is approx. 25% below the open-circuit voltage. Thus, a corresponding solar module with an open-circuit voltage of 60 V has its MPP point at about 45 V. Due to the output voltage limiter, operation close to the MPP point is thus easily possible.

If, for example, you want to use an advantageous voltage of 48 V, the open-circuit voltage is already 64 V at 25° C. and 74 V at −20°, even though the solar module itself is only operated at around 48 V. The output voltage limiter makes it possible to operate the module close to the MPP point. Due to the output voltage limiter, this advantageous configuration is still possible without leaving the extra-low voltage range.

Furthermore, a module with an output voltage limiter could conceivably consist of several photovoltaic cells, e.g. 100 photovoltaic cells. The output voltage limiter can be set in such a way that the module voltage is limited below 60 V. The maximum operating point can then be set to approximately 59 V—still below the ELV limit—and the inverter can operate the solar modules with 100 solar cells at 59 V. The output voltage limiter is most useful when the maximum power point of the module remains below the ELV voltage limit. In this case, the solar module can be operated at maximum power, and during non-operating periods, the output voltage limiter limits the voltage at the contacting portions to the ELV limit.

Furthermore, the output voltage limiter enables the parallel connection of solar modules with different numbers of photovoltaic cells in a solar module system.

Regardless of the foregoing, the protection circuit generally includes at least the output voltage limiter. Thus, when referring to the output voltage limiter, the output voltage limiter may be understood as a protection circuit including an output voltage limiter.

Basically, the protection circuit or the output voltage limiter of the protection circuit is configured to measure the output voltage of the solar module and to limit the output voltage before the extra-low voltage range is exceeded, i.e. before leaving the extra-low voltage range. The output voltage limiter is also preferably adapted to deactivate during normal operation when electrically connected to an inverter, as soon as the inverter sets a voltage that is below the extra-low voltage. However, the protection circuit or output voltage limiter itself is not an inverter. Rather, the protection circuit is such a simple electronic circuit that it can be laminated directly into the solar module between the planar elements.

Preferably, the output voltage limiter includes at least one, preferably a plurality of transistors. The output voltage limiter preferably includes less than 6 transistors, preferably at most 4 transistors. Even though we are referring to transistors here, the transistors can be semiconductor components in particular. In principle, a semiconductor component can also be designed as a diode or voltage comparator. In most cases, however, such a semiconductor component in the present application is a transistor, so that the terms transistor and semiconductor component are interchangeable in the present application. Preferably, the protection circuit thus includes a transistor, and the transistor itself may be a MosFET, FET, pn junction, or any other type with transistor function.

When the output voltage limiter is active, the transistor heats up. Therefore, in a protection circuit including the output voltage limiter formed inside the solar module, the transistor is arranged in such a way that the heat can be easily dissipated. For example, the transistor can be formed in direct thermal contact with an edge portion of the solar module. Furthermore, it is conceivable that the transistor can be short-circuited in case of excessive heating. In this case, almost no more power is dissipated at the transistor. However, the associated solar module then no longer contributes to energy generation. The transistor is particularly preferably configured as a MOSFET transistor.

Optionally, the protection circuit can include a reverse polarity protection, which is designed to protect the solar module from installation with incorrect polarity. Preferably, the reverse polarity protection includes at least one diode, also called a reverse polarity protection diode.

To reduce the current flow through the reverse polarity protection diode, several diodes can be connected in parallel, with each diode carrying a portion of the total current and generating less heat.

This reverse polarity protection protects a solar module connected in parallel with other solar modules from reverse current. If a single solar module is shaded and cannot feed current into the solar modules connected in parallel, the reverse polarity protection blocks reverse current into this solar module.

Highly passivated photovoltaic cells have a (negative) breakdown voltage that is usually higher than the ELV voltage, e.g. 80 V. Since the reverse polarity protection blocks the current even in the case of extreme shading (the module internal voltage is 0 V in the worst case), no reverse current can flow from other solar modules connected in parallel into the shaded solar module. Thus, the reverse polarity protection also contributes to the voltage limitation.

In addition, the reverse current in the conventional solar cells creates hotspots, which can be prevented by reverse polarity protection. This is necessary for a solar module made of planar elements made of plastic, since high temperatures can alter the plastic material.

The heat generating elements, e.g. the transistor and the diode of the protection circuit, are preferably located near the contact elements of the solar module. In particular, the positive contact element is preferable, since in most diodes the heat sink is located at the cathode and the cathode of a reverse polarity protection diode is connected to the positive contact element of the solar module.

In general, it is preferred that the heat sink of the heat generating elements is located on the contact elements of the solar module near the contacting portions.

The contacting portion of the solar module is in contact with an electrically conductive element, in particular a module connection structure, in order to be able to connect the solar modules to each other. Heat can also be dissipated well via this module connection structure.

The extra-low voltage cannot generate electric arcs and therefore the electronic components can be laminated with air bubbles. Air bubbles allow locally thicker laminate structures in the protection circuit area, e.g. a 1.2 mm surface mount device can locally increase the overall thickness of a solar module laminate to 2.21 mm if the solar module laminate has a thickness below 2 mm in all other areas.

Overall, the protection circuit or the output voltage limiter can ensure safe use of the solar module at all times. For example, during transport, when the solar module is touched unintentionally; during commissioning, when the solar module is connected to lines, in particular string lines; during operation, so that the lines, in particular string lines, are never above the extra-low voltage range; and when the solar module is touched during operation, during dismantling of the solar module.

Further optionally, the protection circuit may include an overload fuse. The overload fuse can limit the currents in the event of an extreme overload, such as a lightning strike. The solar module is then switched off.

Particularly preferably, the protection circuit thus includes the output voltage limiter, the overload fuse and the reverse polarity protection, or at least one of these components.

Preferably, the output voltage limiter is arranged within the solar module. Particularly preferably, the protection circuit, in particular including the output voltage limiter, the reverse polarity protection and the overload fuse are arranged within the solar module. This means that the output voltage limiter or the protection circuit is arranged between the two planar elements. Preferably, the components are then designed as SMD components (Surface Mount Device) and are therefore particularly flat. In particular, the components are smaller than 2 mm, preferably smaller than 1.2 mm. This means that the components are not higher than the photovoltaic cells and can advantageously be sandwiched between the two planar elements. The transistor and the reverse polarity protection can heat up and are preferably arranged in direct thermal contact with an edge region of the solar module.

Furthermore, an ELV protection circuit could be configured as a DC/DC converter to convert the internal module voltage to an external voltage below the ELV level. This circuit is more complex and uses more than one transistor and additional components.

This is different from conventional solar modules, which do not have reverse polarity protection and/or an output voltage limiter and/or a fuse to protect against extreme currents.

Independent of or in addition to the above, the protection circuit can also be part of the solar module laminate, i.e. also located between the two planar elements.

In an advantageous embodiment of the invention, the output voltage of the solar module is always within an extra-low voltage below 60 V, in particular during operation, handling, in particular installation, of the solar module and during transport of the solar module.

This means that the solar module is always limited to the ELV range. For example, sun can shine on the solar cells when transporting or handling the solar module. This causes a voltage to be present at the contacting portions. According to the invention, this voltage must always be in the ELV range, i.e. below 60V.

In other words, the output voltage limiter or the protection circuit with the output voltage limiter is configured so that the output voltage of the solar module always remains below 60V. Alternatively, the number of photovoltaic cells is selected so that the output voltage always remains below 60V.

Regardless of or in addition to what was previously described, in a further advantageous embodiment of the invention, the output voltage limiter is part of the protection circuit. The protection circuit preferably further includes the reverse polarity protection and/or the overload fuse as components.

Preferably at least one of the components of the protection circuit is connected to at least one of the contact elements. Particularly preferably, a heat sink of the component is connected to at least one of the contact elements.

Regardless of or in addition to what was previously described, in a further advantageous embodiment of the invention, the protection circuit is arranged between the planar elements. In particular, the protection circuit is laminated between the planar elements.

In general, the composite of the photovoltaic cells and all components between the two planar elements may also be referred to as a solar module laminate.

Regardless of or in addition to what was previously described, in a further advantageous embodiment of the invention, the area between the two planar elements is filled with a filler. Preferably, a plurality of air bubbles, also known as air pockets, are disposed between the two planar elements, wherein the air bubbles are enclosed by the filler.

Preferably, the air bubbles are larger than 0.1 mm in their greatest direction of extension, and particularly preferably they are also larger than 0.5 mm. The air bubbles can also be larger than 1 mm in their largest direction of extension. Due to the extra-low voltage and the physically suppressed risk of an electric arc, it is permissible for air bubbles to be located directly adjacent to any conductive elements in the solar module. This facilitates the manufacturing process of the module.

In a further advantageous embodiment of the invention, at least one of the contacting portions, in addition to electrical contacting when the output voltage is tapped, is also designed for mechanical contacting of the solar module. As a result, the solar module can be mechanically arranged on a bearing structure via the at least one contacting portion.

Preferably, all, in particular both, contacting portions are designed accordingly. The advantage here is that a single element is used for both mechanical and electrical contacting. This means that there is no need for additional connecting elements for mechanical contacting or connection. Preferably, the mechanical contacting of the solar module takes place exclusively via the contacting portions. This also includes cases in which a connecting element that comes into contact with the contacting portion also comes into contact with other parts of the solar module, for example the planar elements.

An advantageous further embodiment of the invention provides that the positive contact element and the negative contact element are preferably at least substantially plate-shaped, in particular strip-shaped. In this case, the positive contact element is arranged on a first side of the solar module as seen in a top view of the solar module, and the negative contact element is arranged on a second side of the solar module as seen in a top view of the solar module, wherein the second side is opposite the first side.

This has the advantage that the solar module can be mechanically contacted on two sides via the corresponding contacting portions. In this way, the solar module can be mounted in a particularly stable manner. For example, the solar module can be suspended on the first side and on the second side. The first side and the second side are preferably transverse sides of the solar module. The length of the first side and the second side then define the width of the solar module. The plate-shaped design of the contact elements also has the advantage that they are flat and can be easily enclosed between the two planar elements.

In an advantageous embodiment of the invention, the positive contact element extends continuously along the first side and the negative contact element extends continuously along the second side.

This provides a particularly wide range of possibilities for cell contacting. In addition, the mechanical power dissipation from the solar module is particularly good.

According to an advantageous further embodiment of the invention, the positive contact element and the negative contact element include portions at at least one end, preferably at two ends, which extend beyond the planar elements and at which the contacting portions are formed.

In this way, the contacting portions can be formed outside the planar elements and are thus particularly easy to contact. Preferably, the portions or the contacting portions extend beyond the planar elements in an extension of the edge of the first or the second side. They are thus arranged at an edge of the solar module. Alternatively, however, the portions where the contact elements extend beyond the planar elements may also be located at another position, for example in the center. Combinations thereof are of course also conceivable.

An advantageous further embodiment of the invention provides that the positive contact element and the negative contact element are arranged, in particular, completely within an area of the two planar elements and the solar module can be contacted via at least one hole or bore passing through the solar module.

This results in a particularly compact solar module whose external dimensions are determined only by the dimensions of the planar elements. The contacting portions are exposed, for example, within the planar elements through the holes. Alternatively or additionally, the contacting portions can also be led outwards and placed around the edge of one of the planar elements without extending substantially beyond the area or face of the planar elements. The holes may pass completely through the solar module. Alternatively, it would be conceivable for the holes to extend only through one of the planar elements to the contacting portion.

In a further advantageous embodiment of the invention, at least one of the contacting portions is in contact with a spiky metal part in the vicinity to the bore. The spiky metal part can be configured as a crown washer or a serrated washer.

In a further advantageous embodiment of the invention, the solar module includes a seal body, in particular a seal shoe, which is formed from rubber, in particular from ethylene-propylene-diene rubber. The seal body surrounds an edge of the solar module and is configured to seal the hole on both sides.

Since the seal body surrounds an edge of the solar module, one seal body can seal the hole on both sides. One part of the seal body lies on one planar element and another part of the seal body lies on the other planar element. The seal bodies can thus protect the contacting portion from moisture and corrosion. As an alternative to a rubber material, the seal body could also be made of polypropylene or of silicone, for example. Another conceivable plastic material would be polyethylene, polyvinyl chloride, neoprene or nylon. Particularly preferably, a seal body in the form of a sealing sheet, in particular made of liquid EPDM or butyl, can be applied to the solar module at the contacting portions. In this way, the seal body will hold better to the solar module and will not get lost. Alternatively, a glue film can also fix the seal body, regardless of the material.

The seal body can have an additional function to carry information such as a label or an RFID transponder with the module data, module polarity and/or other information.

The seal body protects the contacting portions of the module during transportation and storage.

In addition, the seal body can secure the serrated washer or crown washer or other spiky conductive part directly over the module connection structure, and when the module is assembled, the screw pushes the metal spikes of the serrated washer or crown washer through the seal body and into the module connection structure.

An advantageous embodiment of the invention provides that the solar module includes a plurality of photovoltaic cells which are connected in series or are connected in series and in parallel.

By connecting a plurality of photovoltaic cells, the output voltage and output current of the solar module can be advantageously varied. As described above, the output voltage can be increased by connecting the cells in series. The current is constant in all photovoltaic cells connected in series. The output current can be increased by connecting the cells in parallel.

In an advantageous further embodiment of the invention, the at least one photovoltaic cell includes a preferably circumferentially continuous edge protection which surrounds the photovoltaic cell at its edges.

The edge protection serves as cell edge reinforcement. This prevents the growth of mechanical cracks at the edge of the photovoltaic cell. This increases the mechanical load capacity of the solar module and extends its service life.

According to an advantageous further embodiment of the invention, the at least one photovoltaic cell includes a light-permeable protective layer. Preferably, this protective layer is made of a plastic from the group of epoxy resins, polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer, polyvinyl fluoride or polyamide.

The protective layer can be applied on the entire surface or only partially. Further, the protective layer can be applied after soldering of cell interconnecting ribbons or wires.

The light-permeable protective layer is in particular a protective lacquer or protective coating. This has the advantage that mechanical stresses can be relieved, so that breakages are reduced. In addition, the protective layer can serve as a moisture barrier. Particularly preferably, the protective layer is designed in such a way that it serves as an adhesion promoter to the planar elements.

The photovoltaic cells usually consist of brittle materials, for example silicon wafers. During the production or handling of the wafers or photovoltaic cells, micro-fractures can occur on the face and especially at the edges thereof. If the solar module is bent later, forces act on the photovoltaic cell. In particular, inhomogeneous forces occur in the edge area, i.e. at the edges, of the photovoltaic cell or the wafer. The protective layer, which can be configured to adhere well as a lacquer, can dissipate a large part of these forces and the existing cracks do not grow any further. Reducing such cracks also reduces the generation of, for example, hotspots, which in turn can lead to fires.

An advantageous further embodiment of the invention provides that the at least one photovoltaic cell is formed as a bifacial cell or as a monofacial cell.

The advantage of the bifacial cell is that the solar module can be formed as a bifacial solar module which collects light on two flat sides. This achieves a particularly high degree of efficiency. The design as a monofacial solar module, on the other hand, has the advantage that this is fundamentally simpler. Thus, a simpler and cheaper construction of the solar module can be achieved. In the case of a bifacial cell, the cell can preferably include a white back foil or layer to form a monofacial solar module. Alternatively, one of the planar elements may include a corresponding white layer or white color pigments.

In a further advantageous embodiment of the invention, the two planar elements are symmetrical at least in a portion in which the at least one photovoltaic cell is arranged.

In this context, symmetrical is understood to mean in particular symmetry with respect to a symmetry plane which is arranged centrally between the two planar elements and is aligned parallel to the two planar elements.

If the planar elements are formed symmetrically with respect to each other in the portion in which the at least one photovoltaic cell is arranged, the photovoltaic cells can be arranged in a mechanically at least substantially neutral portion. In the neutral portion, bending is possible without breaking the photovoltaic cells.

An advantageous embodiment of the invention provides that the two planar elements are completely symmetrical.

On the one hand, this improves the described effect, since the planar elements are completely symmetrical. On the other hand, the planar elements can then be manufactured as identical parts. This has advantages in manufacturing and assembly. As described above, in a preferred embodiment the contacting portions protrude from the solar module at the edge. This simplifies production, as the solar module with protruding contacting portions can be manufactured in a single operation.

In an advantageous embodiment of the invention, a first planar element of the two planar elements is longer than a second planar element. The first planar element then includes an extended portion which extends beyond the second planar element, the extended portion being bent in the direction of the second planar element and being connected to the second planar element, in particular by a material bond, in particular with a filler, also referred to as encapsulant.

For example, any material or mixture of materials such as polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer, polyvinyl fluoride or polyamide can be used as the encapsulation material. The encapsulation material or even the planar elements may have the function of filtering harmful or non-beneficial wavelengths of light to protect the area under the parts, such as ultraviolet light.

In other words, the first planar element can be bent around the second planar element. Hence, the extended portion traverses a separation portion between the first and second planar elements and protects it. Thus, the solar module can include a particularly well protected edge. This edge can be used, for example, as a top edge at a position in which the solar module is particularly exposed to environmental influences, in particular rain. Merely for example, the edge may be a longitudinal side of the solar module.

Such a solar module can be produced, for example, simply by subsequently heating and bending the extended portion. In this case, it would be conceivable to fuse the extended portion to the second planar element, in particular to weld it, or to glue the extended portion to the second planar element.

According to an advantageous embodiment of the invention, the solar module includes at least one wind release opening. Preferably, the solar module includes a plurality of wind release openings which together define a wind permeable area within an area or surface of the solar module.

The solar module includes a large surface area for collecting solar energy. This causes large forces to act on the solar module when the solar module is mounted in a location where the large area is exposed to wind. Known solar modules can therefore hardly be mounted in wind-exposed locations.

If the surface of the solar module is penetrated by the wind release opening, as is the case here, the air flow of the wind is split up and flows past the surface to the edge and through the wind release opening in the solar module. This allows part of the air mass of the wind to flow through the solar module with a short flow path. This reduces the force acting on the solar module.

Specifically, this force is caused by the wind pressure of the wind acting on the solar module or on a reference surface of the solar module. The force acting on the solar module increases with the wind pressure and the reference surface. By means of the wind release opening, this reference surface can be reduced so that the force is reduced.

Preferably, the wind-permeable area is at least 0.2 cm². Particularly preferably, the wind release openings have different sizes. In this way, larger wind release openings can be arranged at portions of the solar module that are particularly susceptible to loads.

Due to the design of the planar elements made of plastic, the wind release openings can be separated particularly easily. For example, the wind release openings can be sawn, milled, lasered, beam cut or punched. In addition, the wind release openings further reduce the weight of the solar module.

An advantageous embodiment of the invention provides that the area permeable to wind represents 1% to 60%, preferably 1% to 30%, more preferably 5% to 20% of the area of the solar module.

The larger the wind-permeable area, the smaller the area usable by photovoltaic cells. With the values given above, there is a particularly good ratio between the two interacting values. In simplified terms, the surface area of the solar module can be assumed to be the flat surface area of a planar element.

In a further advantageous further embodiment of the invention, the plastic of the planar elements includes at least one of the following plastics: Polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer, polyvinyl fluoride or polyamide.

In this way, the planar elements can be produced easily and cost-effectively. The plastics are readily available materials with the desired properties for the solar module, in particular with regard to density, mouldability, hardness, elasticity, breaking strength, temperature resistance, heat resistance and electrical insulation. The operation at ELV reduces the electrical stress on the plastics and insulation sections. This lower stress reduces the degradation effects that solar modules operated at high voltages suffer from.

An advantageous embodiment of the invention provides that the solar module includes at least one wave-like or wave-formed reinforcement portion in which at least the two planar elements are wave-like. Preferably, the solar module includes a plurality of wave-like reinforcement portions in which at least the two planar elements are wave-like. Alternatively or cumulatively, the solar module includes an embedded reinforcing mesh, in particular a laminated fabric mesh.

Alternatively, this mesh can be made of conductive wires, especially metallic ones, and these metallic wires can have the additional function of a ribbon for conducting the current in the module. A mesh can be very well impregnated with the encapsulant-if used-and provide a good connection. The metal mesh is usually made of metals, metal layers or alloys of Al, Sn, Au, Ag, Ni, Pb, Cu, Fe, Mn, Cr.

The reinforcement portions make the solar module generally more stable. Thus, the solar module can be exposed to higher forces during operation without the solar module being damaged. The reinforcement portions can also locally stabilize the solar module at particularly vulnerable points. For example, the reinforcement portions can thereby relieve the portion in which the cells are arranged.

In an advantageous embodiment of the invention, the two planar elements each include a thickness of at most 2.5 mm, preferably at most 1.0 mm and particularly preferably at most between 0.75 mm and 0.1 mm.

The planar elements include a flat, at least substantially planar shape. The planar elements are therefore plate-like. The thickness is small relative to the other dimensions of the planar elements, i.e. the length and the width. With a maximum thickness of 2.5 mm, the planar elements made of plastic can be manufactured in a significantly smaller thickness than glass planar elements. This further reduces the weight. Particularly preferably, the planar elements are a maximum of 0.75 mm thick. This means that the raw material for the planar elements can be in the form of rolls. The planar elements and thus the solar modules can then be produced very easily in different lengths according to customer requirements.

The planar elements can have a structuring or micro structuring. This can improve the lamination process or achieve certain optical or physical properties on the inside or outside of the solar module.

According to an advantageous embodiment of the invention, the solar module includes a width of between 0.4 m and 1.6 m, in particular between 1.1 m and 1.4 m.

Thus, the planar elements each include a width of between 0.4 m and 1.6 m, in particular between 1.1 m and 1.4 m. The width is understood to be the extension of the corresponding surface in the transverse direction. The specified widths enable a size of the solar module that is suitable for transport and installation. The solar module is therefore user-friendly to handle. At the same time, the width allows a sufficiently large area for the photovoltaic cells. In addition, the planar elements as large rolls can be used particularly effectively for manufacturing the solar modules.

In principle, however, it would be conceivable that the width of the solar modules is significantly greater than 1.4 m. For example, it would be conceivable for the solar modules to include a width of up to more than 5 meters, in particular around 6 meters. Then the solar modules are preferably rolled up into a roll as already described.

An advantageous embodiment of the invention provides that the solar module includes a length of at least 1 m, 2 m or at least 2.5 m. In principle, however, the solar module could be manufactured in lengths of 0.1 m to more than 15 m.

Thus, the planar elements each include a length of at least 1 m, 2 m or at least 2.5 m, respectively. Length is understood to be the extension of the corresponding surface in the longitudinal direction. The length is the largest dimension of the solar module or the planar element. A minimum length of 1 m allows a high number of photovoltaic cells and/or series or parallel connection of the cells.

The above mentioned planar elements are not limited to planar elements made of plastic, such as in particular polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer, polyvinyl fluoride, polyamide or from the group of epoxy resins. A combination of one planar element made of glass and one planar element made of plastic or a combination of two planar elements made of glass or a combination of two planar elements made of plastic have the same advantageous effects of the extra low voltage system. If the planar element is made of glass, the thickness of this planar element is preferably less than 4 mm and particular preferably less than 3 mm. Also a combination of a thin glass layer with a plastic layer for a planar element is possible: The glass layer has very good weatherability properties while the plastic layer ensures an improved mechanical stability of the solar module. In this case, the thickness of the glass layer is preferably less than 3 mm, and more preferably less than 2 mm. The user can select any combination mentioned above according to the desired properties for his application.

In a further advantageous embodiment of the invention, the electrically uninsulated exposed contacting portions are formed of a copper alloy, an aluminum alloy or an iron alloy with or without a surface protection of at least one of the following metals or alloys thereof: Sn, Au, Ag, Ni, Pb, Cu, Al, Fe, Mn, Cr.

The surface protection is in particular a wear and/or corrosion protection. This ensures a connection with low resistivity and extends the service life of the contacting portions and thus of the entire solar module.

Particularly preferably, the contacting portion is a flat metal plate with a surface-core-surface structure in section. In this case, the materials of the layers can be as follows (surface-core-surface): Sn—Al—Sn, Ni—Al—Ni, Ag—Al—Ag, Sn—Cu—Sn, Ni—Cu—Ni, Ag—Cu-Ag and In—Cu—In. The above metals can be in alloys of these materials to improve corrosion resistance, solderability, mechanical properties or conductivity.

In a further advantageous embodiment of the invention, the solar module includes ribbons for electrically connecting the photovoltaic cells to each other.

Hence, the electrical contacts within the module are formed by ribbons, for example. These ribbons, which connect photovoltaic cells and other electrical components within the solar module, can be made of any material that has a solderable surface and is conductive.

Again, the previously mentioned materials and surfaces have advantageous properties and particularly advantageous are the combinations (surface-core-surface): Sn—Al—Sn, Ni—Al—Ni, Ag—Al—Ag, Sn—Cu—Sn, Ni—Cu—Ni, Ag—Cu—Ag and In—Cu—In.

Electrical connections, also called ribbons, within the solar module, especially on the photovoltaic cells, should be as thin as possible. An average thickness of less than 0.2 mm, preferably a thickness of less than 0.1 mm, and especially preferably a thickness of less than 0.085mm is preferred to reduce mechanical stress in the photovoltaic cell. Moreover, a connection with such flat metallic plates reduces the unevenness on the outer surface of the solar module.

An advantageous further embodiment of the invention provides that the solar module includes at least one fastening body for connecting the two planar elements to one another. The fastening body may in particular be a rivet. The rivet may be made of plastic, in particular polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer, polyamide or from the group of epoxy resins. Alternatively, the rivet can be made of metal.

The fastening body serves in particular to stabilize the solar module. The solar module or the two planar elements include through-holes. The fastening body is then inserted into the hole from one side and can be held on the other side, for example, by means of a counter plate. In this case, the counter plate is preferably also part of the solar module and in particular not part of a bearing structure. Particularly preferably, the fastening element is held to the planar elements and/or the counter plate by means of an adhesive. Adhesive can also be formed between the counter plate and the corresponding planar element. Since the solar module is operated in the extra-low voltage range, a conductive fastening body, for example made of metal, can also be used.

Furthermore, the problem is solved by means of a solar module system which includes a plurality of the solar modules described above and a bearing structure which electrically connects and supports the plurality of solar modules. Preferably, the solar modules are connected in parallel. Particularly preferably, all solar modules are connected in parallel.

Since the solar modules used in the solar module system are the solar modules already described, all individual aspects and advantages of the individual solar modules can be transferred at this point. However, the solar modules also generate further advantages for the solar module system.

Since the solar modules used are operated in the extra-low voltage range, the bearing structure of the solar module can be used directly for the power line. No specially insulated string cables or connectors are necessary. This also simplifies feeding into the public power grid.

Since the solar modules are electrically connected in parallel, it is not necessary to ensure that the parallel-connected solar modules are aligned in the same way. It is true that the parallel connection produces somewhat higher losses than the series connection, because of the accumulating current. However, the solar module can be electrically connected and also mechanically held by a part of the bearing structure, for example a string line, at the same time. Typically, string lines also include metal ropes or metal cables or metal pipes with a large material cross-section, which partially compensates for the poor conductivity. It would also be conceivable to actively incorporate a material with good conductivity into the string lines in order to improve them, for example copper or aluminum strands can be incorporated into a steel cable forming the string line.

Due to the light weight of the solar module and the simple construction of the bearing structure, the solar modules can also be mounted at particularly high altitudes. This is particularly advantageous in many applications, like parking slots, streets, storage areas, landfill areas and in agriculture. Farmers in many areas of the world have a problem with too much solar radiation. Shading the field can therefore be beneficial for agriculture in principle. However, it is important that the field is shaded partially only as evenly as possible. If the solar modules are mounted high above the field, they cast a half-shade that moves across the surface of the field as the day progresses. This gives the plants the light they need across the entire light spectrum, but with a reduced integral amount. Thus, the present solar module system can be used to shade a field evenly. This opens the way of using an area for at least two purposes: collection of energy and another purpose like farming.

The lightweight solar modules also result in that only a few supports for the bearing structure, such as poles, need to be anchored in the ground, keeping construction costs low.

Due to the simple construction and operation in the extra-low voltage range, the solar module system can also be set up directly by a non-professional person, e.g. the farmer. For this purpose, the solar module system or at least parts of it can be provided as a kit. This kit then contains all the necessary components and an assembly description.

In agriculture, the bearing structure can also take on other functions. For example, the bearing structure can simultaneously contain suitable nets for insect protection, hail protection, for further shading or as wind protection.

In particular, therefore, the bearing structure is not necessarily limited to fixing solar modules. Rather, the bearing structure can also be used for other parts and plates.

Solar modules with active photovoltaic cells are particularly preferred in combination with planar elements without photovoltaic cells, referred to here as blind panels. This has several advantages: First, shading can be fine-tuned by the ratio of solar modules and blind panels. This provides the farmer with greater flexibility, for example in agrovoltaic systems. Second, like the solar module, the blind panel protects the underlying surface from rain, hail, frost, water evaporation, etc. Third, like the solar module, the blind panel can filter out critical wavelengths from the sunlight. And a blind panel without photovoltaic cells is cheaper than a solar module, and the total system cost can be further reduced. Preferably, materials such as polycarbonate, polymethyl methacrylate, polyolefin, silicone, polypropylene, polyethylene, polyethylene terephthalate, polyvinyl chloride, ethylene-vinyl acetate copolymer, polyurethanes, ethylene-tetrafluoroethylene copolymer or polyamide are used for the blind panel.

Overall, the solar modules according to the invention can provide a solar module system with particularly low BOS costs (Balance of System). These BOS costs include all costs of a solar system except the solar module and are usually in a portion of about 50% to 80% for today's systems.

In the solar module system according to the invention, the BOS costs can be kept particularly low for at least the following reasons: Adherence to the extra-low voltage saves the involvement of an electrician. The parallel connection of the modules saves precise planning or alignment according to the sun. The low weight of the solar modules enables material-saving support structures and reduces the specific transport weight.

In addition, less material and less weight reduce the CO2 footprint for the system. A particularly good way of further reducing the CO2 footprint would also be to plant fast-growing trees in a targeted and regular manner, which can later serve as poles for the bearing structure.

An advantageous further embodiment of the invention provides that the bearing structure includes a fully electrically conductive module connection structure. The module connection structure is designed to conduct the output voltage of the solar modules and preferably connects the solar modules to each other in parallel. The module connection structure is designed as a frame, a rope or as part of a roof covering.

Hence, the module connection structure simultaneously serves to electrically and mechanically connect the solar modules to each other. This means that no additional bearing structure is required to hold the solar modules. This means that the solar modules are held exclusively by the conductive module connection structure. No additional step of connecting specific connectors is needed, like in standard solar systems.

If the module connection structure is designed as a rope, this has several advantages. Ropes can compensate for differences in length between supports, especially poles. In addition, ropes can always be kept at a certain tension by means of weights. Furthermore, the solar modules can be easily suspended from the rope. Suspending the solar modules allows the solar modules to move, in particular to rotate around the rope axis, so that they can evade. Similar to the principle of leaves on trees, the solar module can therefore escape a force and fall back into its old position after the force has subsided.

The advantage of frame structures, on the other hand, is that they are stiffer and can hold more inclined solar modules. Inclined to horizontally mounted solar modules, for example, can also serve to intercept hail, rain and leaves.

Further, the module connection structure may be formed as part of a roof covering. The solar modules themselves can then serve as a lightweight, rainproof roof and are preferably screwed directly to the module connection structure. To support the load-bearing capacity of the solar module or other covering component, such as blind panels, a strap can be placed between the solar module or covering component and the bearing structure. This strap absorbs the load and limits deflection of the solar module when high loads, such as snow loads, are applied to the roof-like structure. The strap can be made of any material that can withstand tensile forces. Materials such as nylon and polypropylene are preferred. For bifacial photovoltaic cells, the strap should preferably be placed between the photovoltaic cells to reduce shading of the solar module. The strap can be installed over the entire bearing structure or only partially. The strap can be used repeatedly in the structure wherever it is needed.

In another advantageous embodiment of the invention, the module connection structure is directly connected to the contacting portions of the solar modules. Alternatively, the module connection structure is connected to the contacting portions of the solar modules via a connecting element which is designed for electrical and mechanical connection at the same time.

When an element is described as “connected” to another element, the element can be connected directly, i.e. immediate, to the other element or indirectly, via intermediate elements. Since solar modules in the extra-low voltage range do not require special connectors and the like, the contacting portion may be directly connected to the module connection structure. For example, the contacting portions can be formed as contacting portions extending beyond the planar elements. The contacting portions can then further be formed, for example, in the shape of hooks and then be directly connected to the module connection structure. In this case, the module connection structure is designed as a rope, for example.

Furthermore, the contacting portions can also be connected to the module connection structure in that the contacting portions and the module connection structure are arranged next to each other in contacting fashion and are mechanically connected to each other by a connecting element. In this case, the electrical connection is direct and the mechanical connection is at least partially indirect.

Furthermore, the contacting portion could also be located completely between the two planar elements. The contacting portion is then exposed via a hole in the solar module, in particular in the planar elements, and can be contacted through this. The contact is then made as an electrical and mechanical connection via a common connecting element. In this case, the contact is made directly between the contacting portion and the connecting element and directly between the connecting element and the module connection structure.

An advantageous further embodiment of the invention provides that the bearing structure includes a support structure which supports the module connection structure.

In particular, the support structure is that part of the bearing structure which is in contact with the ground on which the solar module system is assembled.

In an advantageous further embodiment of the invention, the support structure is formed from an electrically low-conductive material, in particular wood. In this case, the module connection structure is connected to the support structure without electrical insulation.

Materials with a conductivity at 20° C. of less than 10⁻³ S/m, preferably less than 10⁻⁵ S/m, and particularly preferably less than 10⁻⁸ S/m are referred to as low conductive materials. This has the advantage that the support structure at least essentially electrically insulates the module connection structure. Due to this and due to the extra-low voltage range, the module connection structure can be connected to the support structure in an electrically conductive manner, i.e. without electrical insulation. This means that electrically conductive connecting elements can be used which do not have to be electrically insulated from the module connection structure. For example, the module connection structure can be screwed into the support structure with metal screws.

The use of a support structure made of wood is particularly suitable. In the case of wood, the screws are preferably screwed in such a way that the direction of the fibers runs transversely to the electrical discharge in order to improve the insulation effect.

For example, a bearing structure can consist in particular of a conductive metal sheet as a module connection structure and a non-conductive support structure. In this way, simple busbars can be used to establish electrical and mechanical contact between several solar modules and inverters.

For this purpose, only a slat made of insulating materials such as wood, plastic, stone, etc., which are common in the construction industry, needs to be used as a support structure. Furthermore, a conductive metal sheet such as a conductive metal tape or foil can be used as a module connection structure.

The conductive metal sheet or tape is, for example, a conductive aluminum or copper based alloy tape. The conductive metal sheet may include a protective layer of Ag, Au, Sn, Ni, Cr, Cu, Al, Fe. Alternatively, a thin insulation may conceivably be made of materials such as polypropylene, polyethylene, polyvinyl chloride, EPDM, nylon, or neoprene and may include an adhesive film on the backside to form a tape.

Aluminum is preferred because the screw can easily penetrate such a metal sheet, aluminum includes good corrosion resistance, is available as (adhesive) tape and can be protected by surface treatments such as anodizing or coating with metals of the group Ni, Cr, Sn, Ag, In. Due to the ELV concept, the busbar does not need to be insulated, and the aluminum tape ensures sufficient conductivity to connect all solar modules together.

The conductive metal sheet, in particular the aluminum tape, preferably has a metal cross-section of 3 to 50 mm² and very preferably a cross-section of 8 to 26 mm². The thickness of the metal part of the tape should be thicker than 0.02 mm and less than 2 mm and most preferably 0.05 to 0.4 mm thick. For example, an uninsulated aluminum wire in air has a limited current carrying capacity of about 58 amperes (cross section 10 mm²) or 100 amperes (cross section 20 mm²). For other metals, the preferred cross-section may change.

The use of a thin conductive metal sheet or tape is advantageous because curved structures made of any non-conductive material, such as wooden slats, can be converted into busbars by applying the metal sheet or tape to the structure. The structure can be a newly built structure or an existing structure. Using existing structures lowers the overall cost of the system. The solar module itself is made of plastic planar elements that are flat and can be bent to some extent. The solar module itself can therefore follow curved or bent structures.

According to an advantageous further embodiment of the invention, the support structure includes a profiled, in particular ribbed, surface at least in a connection region with the module connection structure.

This has the advantage that the profiling of the surface increases the surface area, so that the surface conductivity is reduced.

An advantageous further embodiment of the invention provides that the support structure includes at least one pole. In this case, the pole can be connected via a rotary joint to a ground on which the solar module system is or is to be installed. The pole can be moved by the rotary joint between a mounting position resting on the ground and an upright operating position.

Thus, the module connection structure and/or the solar modules can be mounted on the ground. This makes the mounting location more easily accessible and no special aids, such as ladders, are required.

In a further advantageous further embodiment of the invention, the support structure includes rotary joint blocking means, in particular in the form of a hollow body, preferably tubular. The rotary joint blocking means allows the rotary joint to be locked when the pole is in the upright operating position.

Particularly preferably, the hollow body is arranged around the pole. The hollow body can be pushed over the rotary joint after the pole has been erected into the upright operating position or falls over the rotary joint during erection. This blocks the rotary joint accordingly. The pole can thus be stabilized in its upright operating position.

An advantageous further embodiment of the invention provides that the support structure includes a plurality of poles whose rotary joints are aligned in the same direction of action. In this case, the poles are arranged in a line in such a way that the poles can be moved together into the upright operating position with a force directed in the operating direction.

In other words, the poles are lined up along the direction of action. The poles are connected to each other via the module connection structure, for example ropes or bars. If the pole at the front is pulled in the direction of action, it erects and also pulls the following poles upwards via the module connection structure. In this way, a whole row of poles can be erected with the erection of only one pole. This simplifies the assembly process considerably.

In an advantageous further embodiment of the invention, the bearing structure is formed as a busbar including the support structure formed of an electrically low-conductive material and the module connection structure in form of a conductive metal sheet. Preferably, the conductive metal sheet is a tape. The tape is an adhesive tape that will stick with application of pressure, in particular without the need for a solvent or heat for activation. In this way, it is possible to adhere the module interconnection structure directly to the support structure.

The conductive metal sheet preferably has a metal cross-section of 3 to 50 mm² and very preferably a cross-section of 8 to 26 mm². The thickness of the metal part of the tape should be thicker than 0.02 mm and less than 2 mm and most preferably 0.05 to 0.4 mm thick.

In an advantageous further embodiment of the invention, the solar module system includes at least one inverter. In particular, the solar module system includes an inverter module with preferably at least one fuse, a main switch and/or an AC socket.

The inverter module including at least one inverter for converting direct current (DC) into alternating current (AC) is connected in the solar module system. When the inverter is switched on, the inverter synchronizes to the grid feed or generates an AC voltage. The MPP point or the predefined DC voltage, for example 48 V, can be set as a voltage value in the extra-low voltage range by means of the inverter module or the inverter. Particularly preferably, a standard component, for example a 48V DC to 230V AC or 48V DC to 115V AC single-phase inverter or 48V DC to 400V AC three-phase inverter, is used as the inverter.

The inverter module preferably includes at least one fuse, in particular AC fuse, a main switch, in particular AC main switch, and a socket, in particular AC-socket. Preferably, the AC socket of the inverter can be operated by a non-professional person.

Particularly preferably, the inverter module is prepared in such a way that it can be supplied already connected to the DC side of the inverter with the module connection structure and preferably includes a built-in AC fuse, a built-in AC main switch and/or a built-in AC-socket on the AC side.

Particularly preferably, the maximum current of the inverter is below the current carrying capacity of the module connection structure, especially that of the conductive metal sheet.

According to an advantageous further embodiment of the invention, the at least one inverter module is connected in parallel to the module connection structure.

Preferably, the solar module system includes at least two inverters or inverter modules connected in parallel to the module connection structure, in particular at a suitable distance. This means that a plurality of inverters can be operated in parallel on the conductive module connection structure with a plurality of solar modules connected in parallel. The ELV circuit in the solar modules helps with the commissioning of multiple inverters connected in parallel, as each inverter can start up with e.g. 48V and does not exceed its upper voltage limit, which is typically 66V for 48V inverters. The ELV circuit therefore enables operation with standard inverters.

Such a network of parallel solar modules and inverters in ELV has several advantages.

The user does not have to worry about designing the photovoltaic system with acceptable voltage and current windows of the inverters. If the inverter has a power of e.g. 2000 Watt and the solar modules have a power of 200 Watt, an inverter is simply connected in parallel to the modules after every 10 solar modules (10×200 Watt=2000 Watt).

If a solar module or an inverter fails, the current and voltage distribution in the entire network of solar modules and inverters automatically readjusts. This makes the system highly resilient to solar module or inverter failures or grid interruptions during operation.

The user can add or remove a solar module or inverter at any time during operation. The system then reconfigures itself as described.

System set-up is made easier: positive and negative module connection structures, such as busbars, can run uninterrupted throughout the system. Each solar module is connected to the module connection structure, e.g. busbar.

In conventional systems, it is dangerous for the user to disconnect series-connected solar modules during operation because the high voltage causes an electric arc. This electric arc damages the solar connectors and can injure the user. The user must follow a protocol to disconnect, and usually only professionals have this knowledge. In contrast, a non-expert can operate and maintain a solar module system with solar modules connected in parallel. Here, too, the ELV helps as the basic concept of the invention.

When solar modules and inverters are connected in parallel, positive contacting portions are interconnected and negative contacting portions are interconnected by a respective module connection structure, e.g. busbar. Positive and negative busbars are insulated by non-conductive or low conductive materials as support structure, as described before. Preferably, insulation to ground potential is provided for at least one busbar. When both busbars are insulated from ground, the system is floating, so to speak, and an inadvertent connection to ground cannot cause a short circuit. Floating systems are preferred.

The different and exemplary features described above can be combined with each other according to the invention, as far as this is technically reasonable and suitable. Further features, advantages and embodiments of the invention will be apparent from the following description of examples of embodiments and from the figures.

### BRIEF DESCRIPTION OF THE DRAWINGS

Further advantages and embodiments as well as features of the present invention are revealed by the following detailed description of exemplary embodiments made with reference to the accompanying drawings.

In this regard:

FIG. 1 shows schematic views of a solar module, namely as a top view and as a longitudinal section

FIG. 2 shows a schematic top view of a connection between a solar module and a bearing structure

FIG. 3 shows a schematic side view of the representation shown in FIG. 2

FIG. 4 shows a schematic side view of a variant of FIG. 3

FIG. 5 shows a schematic representation of a solar module with one longer planar element and a bended edge

FIG. 6 shows a variant of FIG. 5

FIG. 7 shows a schematic representation of a photovoltaic cell with edge protection

FIG. 8 shows a plan view of FIG. 7

FIG. 9 shows a variant of FIG. 7

FIG. 10 shows schematically the propagation of a crack in a photovoltaic cell

FIG. 11 shows a schematic circuit of a solar module with integrated output voltage limiter, reverse polarity protection and overload fuse

FIG. 12 shows a schematic representation of a position during erection of a solar module system

FIG. 13 shows a schematic representation of a rotary joint used during erection with a pole in an assembly position

FIG. 14 shows the representation shown in FIG. 13 with the pole in an upright operating position

FIG. 15 shows a schematic representation of a solar module system in a first embodiment

FIG. 16 shows a schematic representation of a solar module system in a second embodiment

FIG. 17 shows a schematic representation of a solar module system in a third embodiment

FIG. 18 shows a schematic representation of a solar module system in a fourth embodiment

FIG. 19 shows a parallel connected DC voltage grid of solar modules and inverters at top and the typical current and voltage distribution in such a grid at bottom.

FIG. 20 shows an IV curve of a single photovoltaic cell

FIG. 21 shows the interconnection of photovoltaic cells

FIG. 22 shows solar modules rolled up on a roll

FIG. 23 shows the contacting area of a solar module in plan view at top and shows the same area in cross section at the bottom

### DETAILED DESCRIPTION OF THE INVENTION

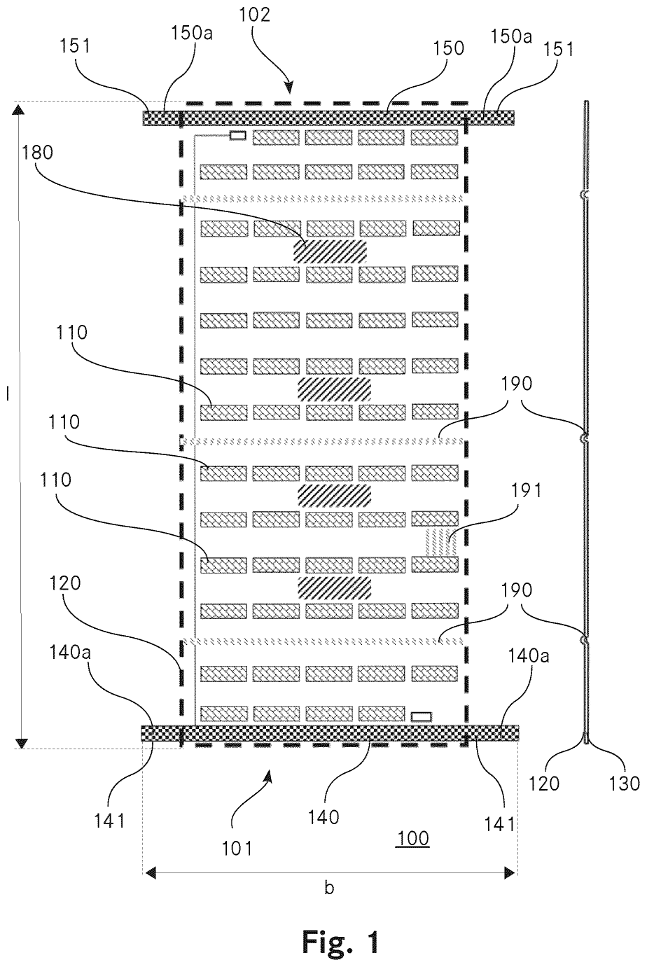

FIG. 1 shows a solar module 100, with a top view of the solar module 100 on the left side of FIG. 1 and a schematic longitudinal section through the solar module 100 on the right side.

The solar module 100 includes a plurality of photovoltaic cells 110 arranged between a first planar element 120 and a second planar element 130. The photovoltaic cells 110 are arranged between the two planar elements 120, 130 as seen in the thickness direction of the solar module 100. The planar elements 120, 130 surround the photovoltaic cells 110 in a sandwich-like manner.

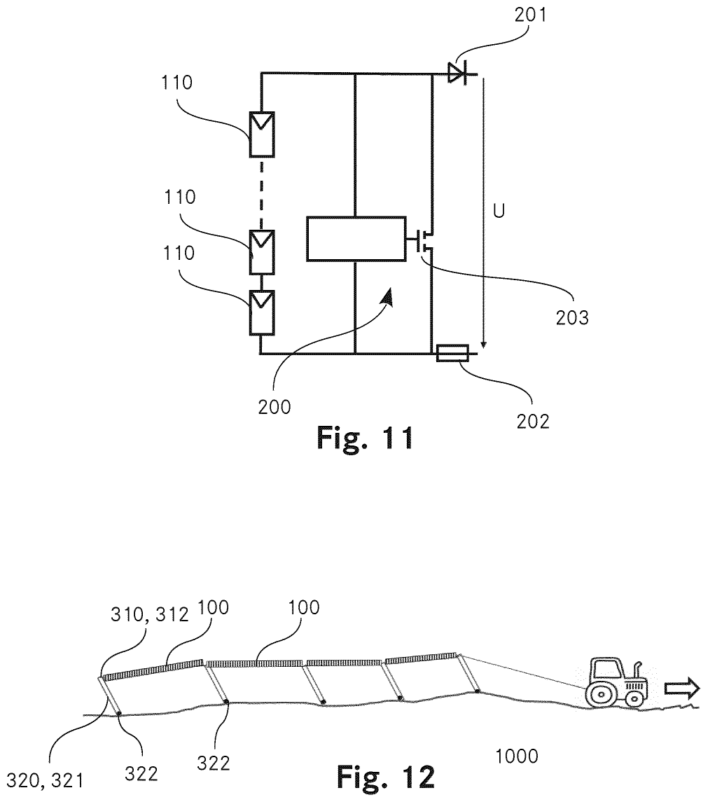

The photovoltaic cells 110 are preferably connected in series. Alternatively, the photovoltaic cells 110 are connected in series and in parallel. This depends in particular on how the output current or output voltage of the solar module 100 should be specified. In this case, the solar module 100 is designed in such a way that the output voltage of the solar module 100 is always an extra-low voltage. Only by way of example is this possible by limiting the number of photovoltaic cells 110, in particular by limiting the number of serially connected photovoltaic cells 110. When photovoltaic cells 110 are connected in series, the voltages of the photovoltaic cells 110 add up. The number of photovoltaic cells 110 can thus be specified such that the output voltage of the solar module 100 always remains in the extra-low voltage range during operation, without the help of an output voltage limiter 200 (see FIG. 11). Alternatives with active limiting of the output voltage are discussed, for example, with reference to FIG. 11.

The two planar elements 120, 130 are at least substantially rectangular in shape, but may in principle include any basic planar shape. As shown in FIG. 1, in particular in the longitudinal section, the planar elements 120, 130 are symmetrical. In particular, the two planar elements 120, 130 are symmetrical at least in a portion in which the photovoltaic cells 110 are arranged. Thus, the photovoltaic cells 110 can be formed in a neutral portion in which no inhomogeneous excessive forces act on the photovoltaic cells 110.

The two planar elements 120, 130 are formed of plastic. Thus, the planar elements 120, 130 can be formed to be extremely impact resistant. Furthermore, the solar module 100 can thus be formed with a low thickness.

The solar module 100 further includes a positive contact element 140 and a negative contact element 150. The positive contact element 140 is arranged on a first side 101 and the negative contact element 150 on a second side 102 of the solar module 100. The first side 101 and the second side 102 are transverse sides of the solar module 100. In principle, however, one or both of the contact elements 140 and 150 could be arranged in a different position. For example, the positive contact element 140 and/or the negative contact element 150 could be arranged centrally as seen in the longitudinal direction of the solar module 100.

As shown, the positive contact element 140 and the negative contact element 150 are plate-shaped, so that they can be arranged at least substantially between the two planar elements 120 and 130. In an alternative embodiment, the entire contact elements 140 and 150 are arranged between the two planar elements 120, 130.

In the embodiment shown in FIG. 1, the positive contact element 140 and the negative contact element 150 are in particular strip-shaped and extend continuously on the respective side. Specifically, the positive contact element 140 extends continuously on the second side 102 and the negative contact element 150 extends continuously on the first side 101, with the positive contact element 140 and the negative contact element 150 extending beyond the planar elements 120, 130. The positive contact element 140 and the negative contact element 150 thus include ends 140a, 150a which extend beyond the planar elements 120, 130. These ends 140a, 150a form portions of the respective contact element 140, 150 which extend beyond the planar elements 120, 130. Even though FIG. 1 shows two ends 140a and two ends 150a, the positive contact element 140 and/or the negative contact element 150 could also include only one end 140a or 150a respectively.

In the example shown in FIG. 1, the portions extending beyond the planar elements 120, 130 are formed as contacting portions 141 and contacting portions 151. The positive contacting portion 141 of the positive contacting element 140 and the negative contacting portion 151 of the negative contacting portion 150 are exposed, i.e. not insulated. This is possible in particular due to the operation of the solar module 100 in the extra-low voltage range, whereby insulation of the contacting portions 141, 151 is not required and no special connectors or the like are necessary.

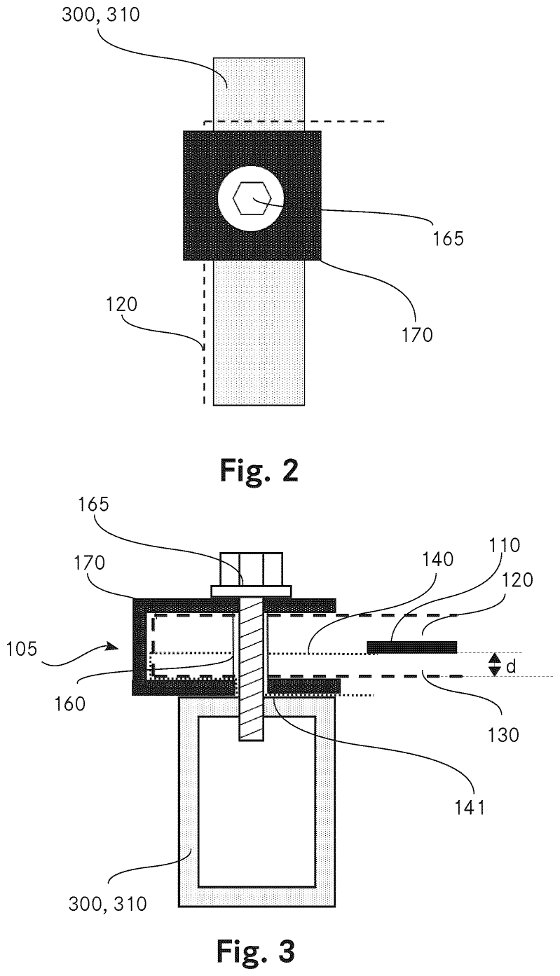

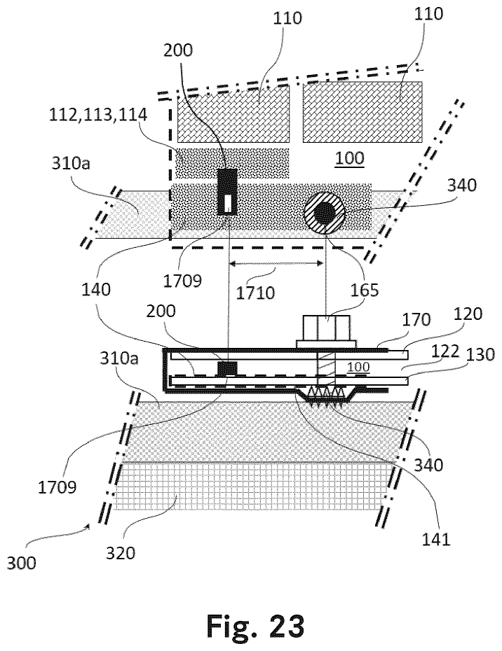

The contacting portions 141 and 151 have a dual function. On the one hand, the contacting portions 141, 151 serve for electrical connection and on the other hand for mechanical contacting. This means that the contacting portions 141, 151 are designed on the one hand for tapping an electrical output voltage of the solar module 100 and on the other hand for mechanically fastening the solar module 100 to a bearing structure 300. The bearing structure 300 is not shown in FIG. 1, but is shown in FIG. 2, FIG. 3, FIG. 4, FIG. 15 or FIGS. 23a and 23b, for example.

Even though two positive and two negative contacting portions 141, 151 are shown in FIG. 1, a single contacting portion 141 and a single contacting portion 151 are of course sufficient. The contacting portions 141, 151 are not limited to the positions shown in FIG. 1. Rather, one or both of the contacting portions 141, 151 could also be arranged centrally instead. Also, the contacting portions 141, 151 do not have to protrude on the longitudinal side of the solar module 100, but can also protrude at any position on one of the transverse sides.

Further alternatively, the contacting portion 141 and/or the contacting portion 151 may not extend beyond the planar elements 120, 130. In this case, the corresponding contacting portion 141, 151 can be completely arranged between the two planar elements 120, 130. In particular, the positive contact element 140 and/or the negative contact element 150 can then also be arranged completely between the planar elements 120, 130.

Alternatively the contacting portions 141 or 151 can be bent around the planar element 120 or 130. The contacting portions 141 and 151 can press onto the bearing structure, which is shown in FIG. 3, 4 or 23.

When both contact elements 140 and 150 are completely arranged between the two planar elements 120, 130 and do not extend beyond the planar elements 120, 130, the external dimensions of the solar module 100 are defined by the dimensions of the planar elements 120, 130. As can be seen in FIG. 1, the solar module 100 includes a length l in the longitudinal direction and a width b in the transverse direction. In FIG. 1, the length l also corresponds to the length of the planar elements 120, 130. However, since the contact elements 140, 150 or the contacting portions 141 and 151 protrude beyond the width of the planar elements 120, 130, the solar module 100 is slightly wider than the width of the planar elements 120, 130. The length l can preferably be at least 0.1 m and particularly preferably at least 1.2 m. The width b can include a value between 0.4 m and 1.6 m, in particular between 1.1 m and 1.4 m. These advantageous dimensions can be realized in particular by the planar elements 120, 130 being made of plastic. In addition, several measures are implemented in the solar module 100 to ensure the stability of such large solar modules 100.

For example, as can be seen in FIG. 1, the solar module 100 includes a plurality of wind release openings 180. The wind release openings 180 form a surface permeable to wind within an area, in particular length×width, of the solar module 100. The air flow of the wind can be divided through the wind release openings 180 so that it can flow past the surface to the edge and through the wind release opening 180 in the solar module 100. Four wind release openings 180 are shown here purely as an example. However, the number of wind release openings 180 may differ. The wind release openings 180 can also include different sizes, so that particularly stressed or susceptible portions of the solar module 100 are especially relieved. For example, more or larger wind release openings 180 can be arranged near the neutral portion or portions in which photovoltaic cells 110 are arranged than in other portions, such as edge portions. Since the first planar element 120 and the second planar element 130 are formed of plastic, the wind release openings 180 are simply incorporable in the planar elements 120, 130.

Alternatively or cumulatively, the solar module 100 may include a wave-like reinforcement portion 190. In this example, the solar module 100 includes three wave-like reinforcement portions 190. The wave-like shape of the wave-like reinforcement portions 190 can be seen particularly well in the longitudinal section in FIG. 1. Here it is clearly visible that the first planar element 120 and the second planar element 130 include wave-like reinforcement portions 190.

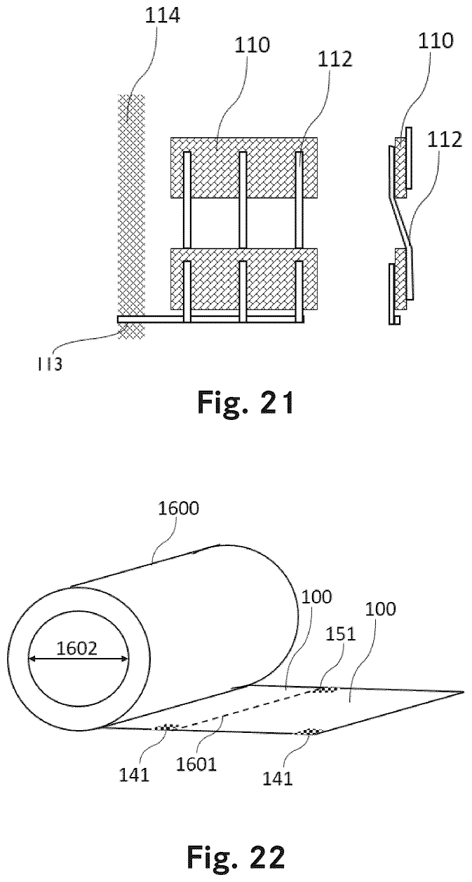

Further alternatively or cumulatively, the solar module 100 may include a reinforcing mesh 191. By way of example, only one portion with a reinforcing mesh 191 is indicated in FIG. 1. However, such reinforcing mesh 191 may be arranged at several portions of the solar module 100 to increase the stability of the solar module 100. The reinforcing mesh 191 can have an additional function to conduct current, which is also shown in FIG. 21.

Overall, the solar module 100 can be subjected to higher forces during operation due to the measures without the solar module 100 being damaged.

FIG. 2 shows a schematic top view of a connection between a solar module 100 and a bearing structure 300. FIG. 3 shows a corresponding side view of the representation shown in FIG. 2.

In particular, FIGS. 2 and 3 show how the contacting portion 141 can make contact when the contacting portion 141 does not extend beyond the planar elements 120, 130. As can be clearly seen in FIG. 3, the positive contact element 140 is arranged within a surface of the two planar elements 120, 130. Here, a hole 160 is arranged in the solar module 100 via which a connecting element 165 can establish a connection with the bearing structure 300. In the example shown in FIG. 3, the contacting element 140 shown in dotted lines is formed as a contacting plate extending outwards and around the edge 105 of the planar element 130 to the bearing structure 300. The contacting portion 141 is arranged next to the bearing structure 300 in a contacting manner and is pressed onto the bearing structure 300 by the connecting element 165 during mechanical connection to the bearing structure 300.

The connecting element 165 thus has a dual function and also makes mechanical contact with the bearing structure 300, in particular a module connection structure 310 of the bearing structure 300. The module connection structure 310 thus serves simultaneously for the electrical and mechanical connection of the solar module 100. The module connection structure 310 is made entirely of conductive material. Transferred to the Figs., this means that the contacting portions 141 and 151 are arranged in direct electrical contact with the module connection structure 310.

Even though FIGS. 2 and 3 show the connection from the solar module 100 to the bearing structure 300 with only one contacting portion 141, the contacting portion 151 of the negative contacting element 150 can also be contacted via a hole 160 and a connecting element 165. It would be particularly preferable if the contact elements 140 and 150 are arranged entirely between the planar elements 120 and 130 and the contacting takes place at the corners of the surface of the planar elements 120, 130. In particular, the contacting can take place at all four corners.

In order to prevent liquid from entering the solar module 100 and in particular the contacting portion 141, the solar module 100 further includes a seal body 170. The seal body 170 is designed in the form of a shoe and surrounds an edge 105 of the solar module 100 as shown in FIG. 3. The seal body 170 can thus be designed to seal the hole 160 on both sides. In this case, one part of the seal body 170 rests on the first planar element 120 and another part of the seal body 170 rests on the second planar element 130. These two parts are connected by a part that surrounds the edge 105.

FIG. 3 again clearly shows that the cell 110 is sandwiched between the two planar elements 120, 130. The thickness of the planar elements 120, 130 is indicated in each case by d and is at most 2.5 mm, preferably at most 1.0 mm and particularly preferably at most 0.75 mm. Particularly preferably, the planar elements 120, 130 are a maximum of 0.75 mm thick. This means that the raw material for the planar elements 120, 130 can be in the form of rolls.

FIG. 4 shows a variation of FIG. 3: Here, a spiky metal part 340 is arranged between the contacting portion 141 and the seal body 170. The spiky metal part 340 presses its spikes into the contacting portion 141 and through the seal body 170 into the conductive portion of the bearing structure 300, namely the module connection structure 310, which is exemplarily formed as a thin conductive metal sheet 310a. The conductive metal sheet 310a covers or partially covers the support structure 320, which is formed of an insulating material such as wood. In this example, the spiky metal part 340 has a cross-section of a crown-shaped washer or a serrated washer.

FIG. 4 shows another detail of the edge of the solar module 100: The solar module 100 includes a protrusion 171 that extends beyond the bearing structure 300. This allows water droplets to form and water to drip off the edge before it gets between the contacting portion 141 and the bearing structure 300.

Further, the fastener 165 preferably includes a washer 166 to distribute the pressure of the fastener 165, the washer 166 preferably sealing the hole 160. One technical solution is to use a sprinkler screw.

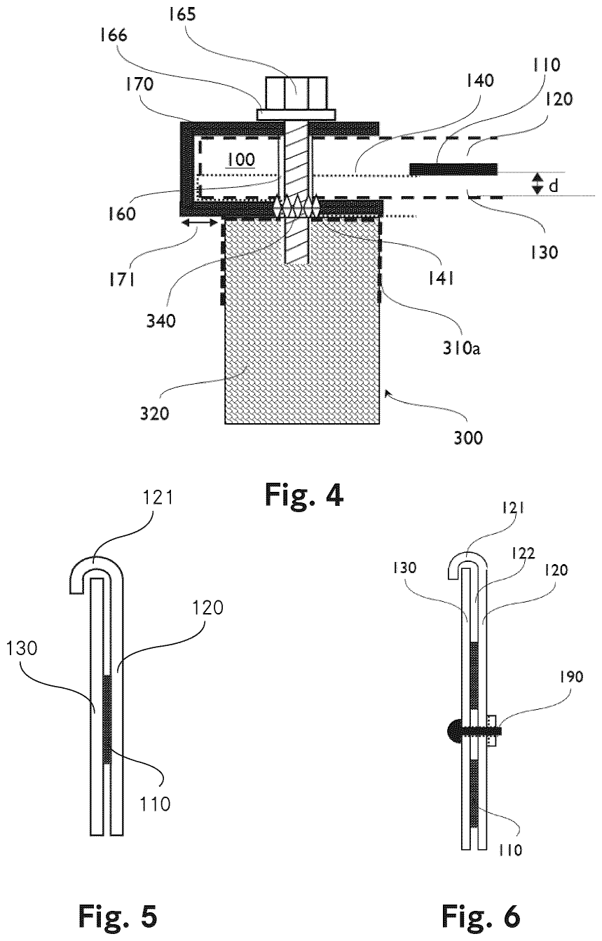

FIG. 5 shows an embodiment in which the first planar element 120 is longer than the second planar element 130. The first planar element 120 then includes an extended portion 121 which extends beyond the second planar element 130. The extended portion 121 is bent over the second planar element 130 as shown in FIG. 4. This traverses a separation portion between the first planar element 120 and the second planar element 130, such that the separation portion is protected by the extended portion 121. This results in a particularly well protected edge of the solar module 100.

FIG. 6 is a modification of FIG. 4. FIG. 6 shows a filler 122 between the two planar elements 120 and 130. This filler 122 has the function of bonding the two planar elements 120, 130, the photovoltaic cells 110 and all other components between the two planar elements 120, 130 together.

The result of this lamination process is a solar module laminate. Due to the extra-low voltage and the physically suppressed risk of an electric arc, it is permissible for air bubbles to be located directly adjacent to all conductive elements such as the photovoltaic cells 110, the ribbons 112, 113, or 114, and the elements of the protection circuit 200 in the solar module 100. At extra-low voltage, the electric field is too low and cannot generate electric arcs, which are first generated in air bubbles. This facilitates the manufacturing process of the module and the filler 122 does not have to fill all the gaps in the solar module 100.

Regardless of the foregoing, FIG. 6 shows an example with a rivet 190. The rivet 190 can be made of plastic or metal or partially made of plastic or metal. Because of the ELV concept, insulation is not required. Preferably, the rivet 190 is arranged between the brittle photovoltaic cells 110. FIG. 6 shows a rivet 190, but the module 100 may include any other number of rivets 190.

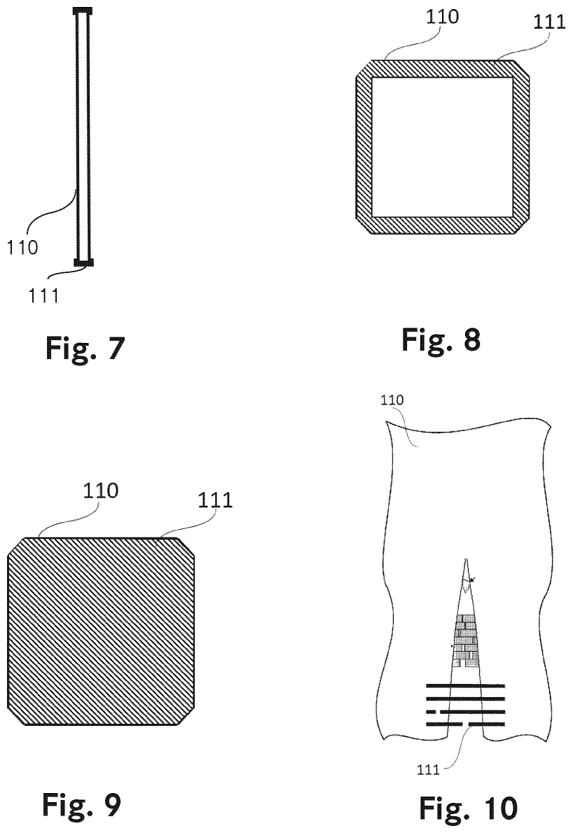

FIG. 7 shows a schematic representation of a photovoltaic cell 110 with an edge protection 111. The edge protection 111 is preferably formed circumferentially continuous and embraces the photovoltaic cell 110 at its edges. The edge protection 111 acts as cell edge reinforcement. The photovoltaic cells 110 are generally made of brittle materials. During manufacture, micro-fractures may occur, particularly at edge regions of the cells 110. If the solar module 100 is bent later, inhomogeneous forces occur. The edge protection 111 can prevent the microfractures from growing.

FIG. 8 shows a top view of a photovoltaic cells 110 of FIG. 7 with a circumferential edge protection 111.

FIG. 9 shows a top view of a photovoltaic cell 110 with an edge protection 111 covering the entire surface of the photovoltaic cells 110.

FIG. 10 shows the mechanisms of crack propagation in a photovoltaic cells 110. The edge protection 111 absorbs the mechanical load.

FIG. 11 shows a possible embodiment as a schematic circuit of a solar module 100. For this purpose, the solar module 100 includes a plurality of serially connected photovoltaic cells 110 and a protection circuit 200. The protection circuit 200 includes an output voltage limiter 203 preferably a reverse polarity protection 201 and preferably an overload fuse 202. The output voltage limiter 203 is preferably configured as a transistor, the reverse polarity protection is preferably configured as a diode and the overload fuse 202 is preferably configured as a fuse.

The output voltage limiter 203 is configured to limit the output voltage U to an extra-low voltage or to keep it within the extra-low voltage range. This has the advantage that operation close to the MPP point is easily possible. In the example shown in FIG. 11, the output voltage limiter 203 is arranged within the solar module 100. Particularly preferably, the entire protection circuit 200, including the output voltage limiter 203, the reverse polarity protection 201 and, if applicable, the overload fuse 202 is arranged within the solar module 100. Most preferably the entire protection circuit 200 is laminated in the solar module 100.

As an alternative to the embodiment shown in FIG. 11, it would also be conceivable in principle if the protection circuit 200 was designed outside the solar module 100 as an external protection circuit 200 with output voltage limiter 203. Hence, alternatively or cumulatively to the limitation of the output voltage U of the solar module 100 discussed in FIG. 1 by limiting the number of serially connected photovoltaic cells 110, an active limitation of the output voltage U by an output voltage limiter 203 is also possible. The limitation could also be done by a DC/DC voltage converter that transforms the internal voltage of the solar module 100 to a voltage below ELV at the contacting portions 141, 151 of the solar module 100.

Preferably, the heat-generating elements such as the diode of the reverse polarity protection 201 or the transistor of the output voltage limiter 203 are located in the vicinity of the contacting portion 141 or 151 of the solar module 100. Preferably, the heat sink of the diode or the transistor is connected to the contact elements 140 or 150 in the immediate vicinity of the contacting portion 141 or 151.

A preferred distance to the connecting element 165 of the solar module 100 is less than 80 mm, preferably less than 40 mm and particularly preferably less than 20 mm.

Preferably, the heat sink is arranged above the module connection structure 310 so that the heat can best be dissipated in the direction of the module connection structure 310.

FIG. 12 shows a schematic representation of a position when setting up a solar module system 1000. The solar module system 1000 includes a plurality of solar modules 100 and the bearing structure 300 which electrically connects and supports the plurality of solar modules 100.

The solar modules 100 are preferably connected in parallel with each other, so that it is not necessary to ensure that the solar modules 100 are aligned in the same way.

The bearing structure 300 includes the module connection structure 310 and a support structure 320. Here, the module connection structure 310 is formed as a rope 312 or traverse and the support structure 320 is formed as a pole 321. The module connection structure 310 is fully electrically conductive and carries the output voltage of the solar modules 100. Thus, the module connection structure 310 is also used to connect the solar modules 110 to each other, preferably in parallel. In addition to the electrical connection, the module connection structure 310 also serves to mechanically connect the solar modules 100 to each other. Preferably, only the module connection structure 310 of the bearing structure 300 and in particular not the support structure 320 of the bearing structure 300 comes into direct contact with the solar modules 100. The support structure 320 is the part of the bearing structure 300 that is in contact with the ground on which the solar module system 1000 is built. Here, the support structure 320, which is formed as poles 321, is connected to the ground via rotary joints 322.

Thus, the poles 321 are configured to be movable by the rotary joint 322 between an assembly position resting on the ground and an upright operating position. FIG. 12 shows an intermediate position between the two positions, which is passed through when the poles 321 are erected. The great advantage here is that the assembly of the module connection structure 310 and the solar modules 100 can take place on the ground.

If the support structure 320, as shown in FIG. 12, includes a plurality of poles 321 whose rotary joints 322 are aligned in the same direction of action, all the poles 321 can be moved together into the upright operating position with a force directed in the direction of action. When the right-hand pole 321 in FIG. 12 is pulled in the operating direction, it erects and also pulls the following poles 321 upwards via the module connection structure 310.

The distance between the individual poles 321 can be 15 to 40 m, for example. Preferably, at least one inverter module or inverter can be pre-mounted on at least one of the poles 321.

The structure shown in FIG. 12 is not limited to one row or line of poles 321. Rather, multiple parallel rows may be formed. These parallel rows can then also be erected together. The distance between the rows is then between 5 and 40 m, for example. Transverse cables or stable transverse stiffeners are then preferably pulled across the rows for stabilization. Furthermore, it would also be generally conceivable that the ropes 312 for the two polarities are guided at two different heights. Then cross ropes can be stretched between the poles 321, which in turn support solar modules 100 or ropes and thus build up a network of ropes above the ground. This network also supports the poles 321 laterally and increases stability.

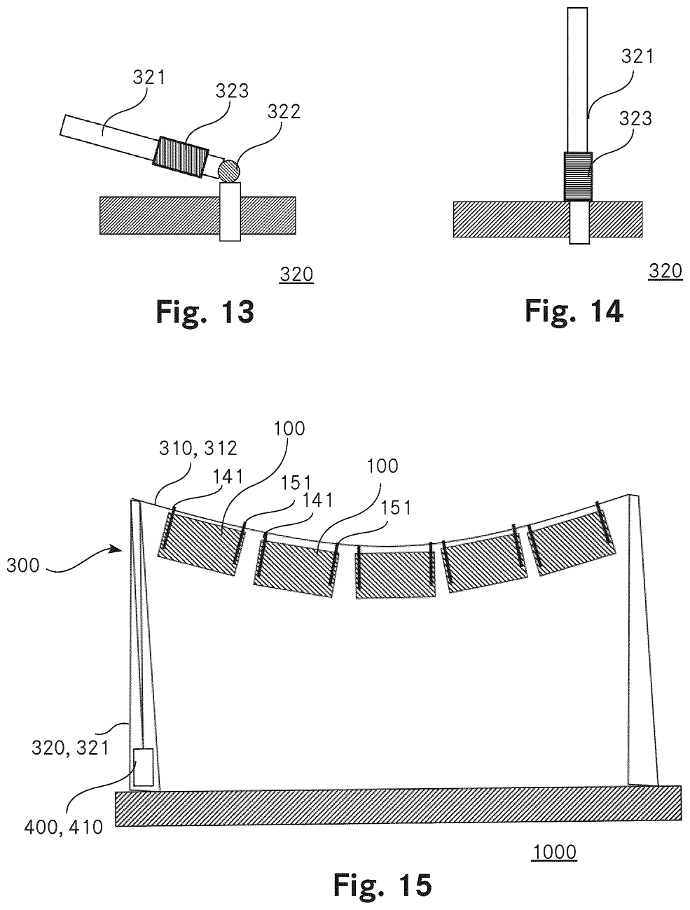

FIGS. 13 and 14 show another advantageous detail in connection with the rotary joint 322. Here, FIG. 13 shows a schematic representation of a rotary joint 322 used in the erection process with a pole 321 in the assembly position and FIG. 14 shows the pole 322 in the operating position.

As can be seen in FIGS. 13 and 14, the support structure 320 includes rotary joint blocking means 323. The rotary joint blocking means 323 are positioned above the rotary joint 322 and are in particular formed as a hollow body. The rotary joint blocking means 323 preferably include an inner shape matching the outer shape of the pole 321. The rotary joint blocking means 323 can be slid over the rotary joint 322 after the pole 323 has been erected into the upright operating position. Particularly preferably, the rotary joint blocking means 323 slide down along the pole 321 during erection and then falls over the rotary joint 322, thereby locking the rotary joint 322 accordingly and keeping the pole 321 stable in its operating position.

FIGS. 15, 16 and 17 show schematic illustrations of solar module systems 1000 in various exemplary embodiments.

In the embodiment shown in FIG. 15, the solar module system 1000 is shown with a module connection structure 310 formed as a rope 312. Here, two ropes 312 are stretched side by side between two poles 321 as a support structure 320 at the same height. The solar modules 100 hang with their positive contacting portions 141 from one rope 312 and with their negative contacting portions 151 from the other rope 312. Such hanging solar modules 100 can rotate about the rope axes, so that a rotatable mounting of the solar modules 100 is given. In this way, the solar modules 100 can avoid a force and fall back into the old position after the force has subsided. When wind holes 180 (shown in FIG. 1) are present, the wind force on the solar module 100 is further reduced. Therefore, a combination of solar modules 100 with wind holes 180 and a rotatable mounting is preferable.

FIG. 15 also shows an inverter module 400 and an inverter 410. The inverter module 400 or inverter 410 is attached to the support structure 320, for example, and is preferably connected in parallel to the module connection structure 310 as shown. Thus, the inverter module 400 or the inverter 410 is connectable or connected in the solar module system 1000. When the inverter 410 is switched on, the inverter 410 synchronizes to the grid feed-in or generates an alternating voltage. In doing so, a predefined DC voltage, for example 48 V, can be set as a voltage value in the extra-low voltage range by means of the inverter 410.

The inverter module 400 may further include an AC fuse, an AC main switch and/or an AC-socket, which would also be arranged in the box indicating the inverter module 400 when transferred to FIG. 15. Preferably, the solar module system 1000 includes at least two inverters 410 or inverter modules 400 connected in parallel to the module connection structure 310 with a certain distance.

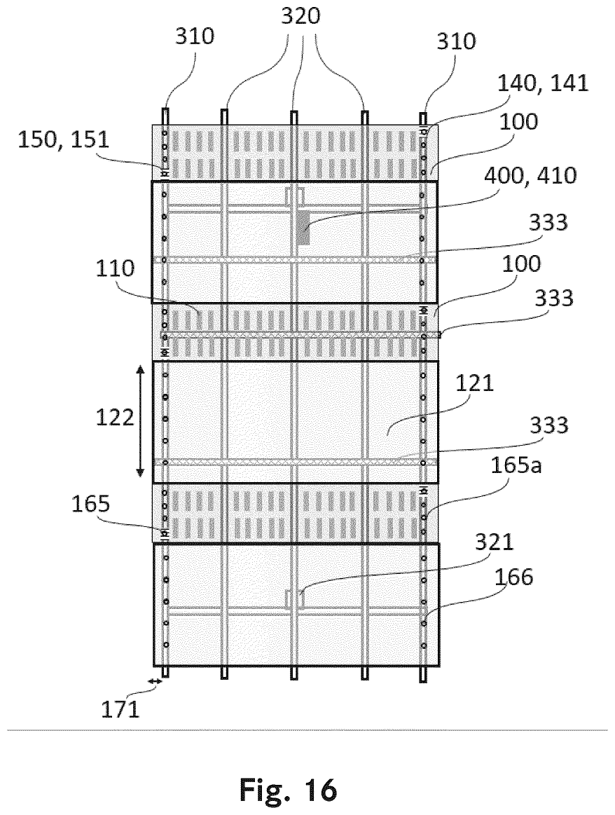

FIG. 16 shows another embodiment of the present invention: A plurality of solar modules 100 are attached to the bearing structure 300 by connecting elements 165 and 165a. For example, the connecting elements 165 mechanically and electrically connect the solar module 100 to the bearing structure 300, and the connecting elements 165a only mechanically connect the solar module 100 to the bearing structure 300.

In this example, the solar module 100 has its contacting portions 141 and 151 on the left and right outer sides, and therefore the module connection structure 310 of the bearing structure 300 is arranged on the left and right sides. The module connection structure 310 may be formed as a conductive slat or the bearing structure 300 may be formed there of a non-conductive slat as a support structure 320 and a conductive metal sheet 310a as the module connection structure 310. In this example, the inverter 400, 410 is connected to at least one of the module connection structures 310 on the low-voltage side.

To improve the load bearing capacity of the solar module 100, a strap 333 may be placed between the solar module 100 and the underlying bearing structure 300. This strap 333 may be made of any insulating or low conductive material such as polypropylene, polyethylene, nylon, and may be of any color. Preferably, the strap 333 is located under or near the connecting elements 165a and is repeated in any number, depending on the mechanical load capacity requirements of this roof-like structure. It should not be located below the connecting elements 165.

The seal body 170 may be formed as a body shoe for protecting the contacting portion 141, 131 of the solar module 100. The solar module 100 overlaps the bearing structure 300 by the distance 171 to allow water drainage (see FIG. 4).

The middle elements of the bearing structure 300 serve only as a support structure 320 and do not contribute to energy distribution.

There are several ways to cover the area under the solar modules 100, for example, to protect it from rain. In this example, the solar modules 100 are arranged at a distance 122 from each other. Planar elements 121 are placed between the solar modules 100 to protect the area below. The planar elements 121 may include an overlap with the solar module 100 to provide better protection from rain.

Optionally, drip water may be collected in a rain gutter on the outer left and right sides and stored in a water reservoir. The planar elements 121 are referred to as blind panels and can be made of any insulating or low conductive material and in any color. In this example, the planar elements 121 are attached in the same manner as the solar module 100 using connecting elements 165a. A strap 333 may be attached in the same manner as previously described.

FIG. 16 shows only one example of how the solar modules 100 are attached to the bearing structure 300. For example, the module connection structure 310 can be located anywhere, such as in the center of the solar module 100. The blind panels are also just an example, and the system could instead consist only of solar modules 100, etc.

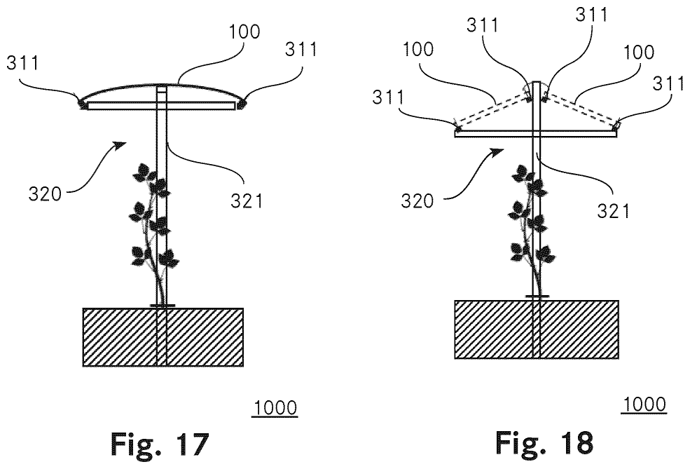

FIG. 17 shows a solar module system 1000 with a module connection structure 310 formed as a frame 311. Here, a curved solar module 100 is stretched over a support structure 320 formed as a pole 321. The curved mounting of the solar module 100 is made possible in particular due to the planar elements 120 and 130 formed symmetrically from plastic. Since the solar module 100 spans the support structure 320, it forms a protective roof for plants growing underneath. Of course, a plurality of solar modules 100 are preferably arranged one behind the other on the frame 311.

The support structure 320 or the pole 321 is made of a material with low electrical conductivity, in particular wood. In this case, the module connection structure 310 is connected to the support structure 320 without electrical insulation. For example, the frame 311 can be screwed directly into the support structure 320 with metal screws. In this case, the screw connection is made in such a way that the direction of the fibers is transverse to the electrical conduction in order to improve the insulation effect.

In FIG. 18, the module connection structure 310 is also formed as a frame 311. However, instead of one curved solar module 100, two solar modules 100 aligned at an angle to each other are used. The solar modules 100 according to the invention are extremely versatile. For example, the structure of FIG. 17 or FIG. 18 can be extended to form a house, such as a greenhouse. The lightweight solar module 100 can form a protective roof or canopy.

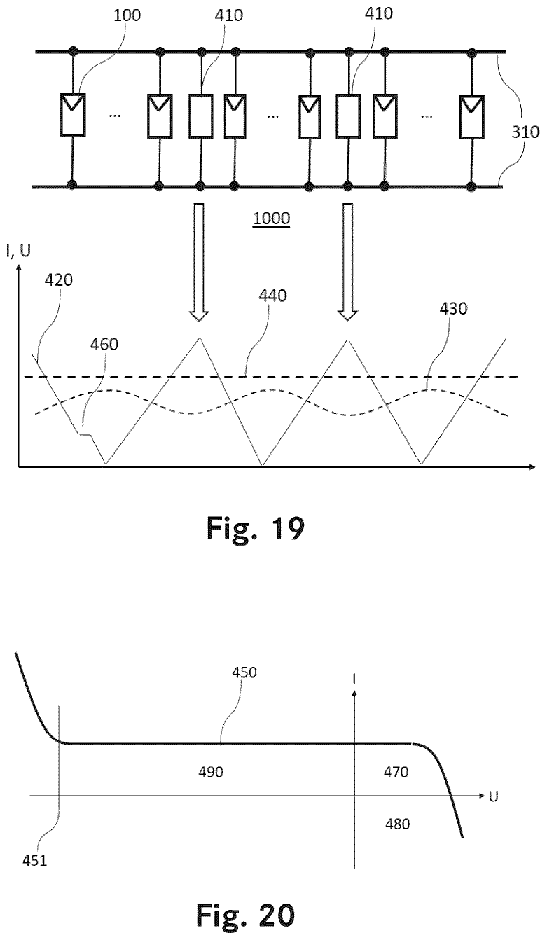

FIG. 19 top shows a solar module system 1000 consisting of a network of multiple solar modules 100 and inverters 410 connected in parallel, which are connected via the positive and negative module connection structure 310, which can be configured as described above.

FIG. 19 bottom shows a typical pattern of current 420 and voltage 430 in this network: current 420 is maximum at the terminals of inverter 410. Voltage 430 is minimum at this terminal. The current 420 has a maximum point at the terminal of the inverter 410, which is limited by the inverter 410 or below by the current of the solar modules 100 caused by the solar radiation. The swing of the voltage 430 is only a few volts or less than one volt. By way of example only, a solar module 100 is defective at section 460, so that the current in section 460 does not increase. The grid will redistribute current and voltage. 440 shows the ELV limit and the system voltage 430 will always stay below this limit.

FIG. 20 shows the IU curve 450 of a single photovoltaic cell 110 indicating the reverse voltage and the breakdown voltage 451. The active region of the photovoltaic cell 110 is located in 470. Section 490 is the reverse voltage region. A single photovoltaic cell 110 “sees” a negative voltage when that cell is shaded and all other photovoltaic cells 110 of the solar module 100 are not. The ELV voltage limitation limits the number of photovoltaic cells 110, or the output voltage limiter 200 limits to a voltage below the breakdown voltage. A photovoltaic cell 110 of a solar module 100 with reverse polarity protection 201 cannot enter the area 480.

FIG. 21 shows the schematic electrical connection of the photovoltaic cells 110: the ribbons 112 connect the photovoltaic cells 110 in series.

Ribbon 113 collects the current and passes it to ribbon 114. Ribbons 112, 113, and 114 can be flat metal wires, plates or metal mesh. In the case of ribbon 114, the mesh runs over a longer section and aids in the stability of the module. Preferably, a mesh of thin copper alloy wires with a wire diameter of 0.001 to 0.2 mm is used.

In general, the metallic connections or interconnections within the solar module 100, especially on the top surface of the photovoltaic cells 110, should be as thin as possible. An average thickness of less than 0.2 mm, preferably a thickness of less than 0.1 mm, and particularly preferably a thickness of less than 0.085 mm is recommended to reduce mechanical stress in the photovoltaic cells 110. In addition, a flat metallic connection reduces the unevenness on the outer surface of the solar module 110.

FIG. 22 shows a rolled solar module: The solar module 100 can be bent to a minimum diameter 1602 and rolled onto a large roll 1600. This solar module 100 may generally be several hundred meters long. At regular intervals, such as every 2 meters, a cut section is integrated, indicated by the dashed line 1601. The contacting portions 141, 151 of the same polarity are connected in parallel across the module boundaries (dashed line 1601). This means that all contacting portions 141 are connected in parallel and all contacting portions 151 are connected in parallel, allowing the user to decide where to cut off a portion of the solar module 110. Since the planar elements 120, 130 are preferably made of plastic, they are easily cut by the user.

Preferably, it is convenient to connect all contacting portions 141 in parallel or to connect all contacting portions 151 in parallel by using a conductive wire mesh.

In another preferred form, the roll 1600 can be manufactured without the internal connection of the contacting portions 141 or 151. Then, the solar modules 110 are electrically separated and the rolled solar modules 110 can be advantageously transported.

FIG. 23 top shows an example of a top view of a solar module 100 in a region of the contacting portion 141 of the contact element 140 of the solar module 100. The same applies to the contacting portion 151.

FIG. 23 bottom shows the corresponding cross-sectional view of FIG. 23 top, with a section along the line connecting heat sink 1709 and connecting element 165.

The figure reduces the elements that are the focus of this description, for example, the protection circuit 200 is shown as only one element 200 and the electrical connections between the photovoltaic cells 110 are not shown.

A solar module 100 is mechanically and electrically connected to a bearing structure 300 via a connecting element 165. The contacting portion 141 of the solar module 100 is located below the lower planar element 130 and the metal spikes of the spiky metal part 340 make the electrical connection to the module connection structure 310 of the bearing structure 300, shown here by a conductive metal sheet 310a. The metal spikes of the spiky metal part 340 penetrate the seal body 170, which is exemplified as a body shoe.

Inside the solar module 100, the protection circuit 200 is connected to the contact element 140 of the solar module 100. Preferably, a heat sink 1709 of the protection circuit 200 is directly connected to the contact element 140. The distance 1710 between the heat sink 1709 and the connecting element 165 is preferably less than 80 mm, more preferably less than 40 mm, and especially preferably less than 20 mm. Furthermore, it is preferred to arrange the heat sink 1709 above the position of the bearing structure 300. A small distance 1710 and proximity to the bearing structure 300 improve heat dissipation from the heat sink 1709 and lowers the temperature, which is important for materials such as plastic.

On the other hand, the protection circuit 200 heats up and this heat dries moisture from the area between the contact element 140 or contacting portion 141 and the bearing structure 300. This drying function reduces corrosion of the contact area.

In addition to reducing corrosion, the protection circuit 200 can be connected to the more corrosion-prone contacting portion 141, 151 of the solar module 100. The heat from the protection circuit 200 reduces moisture by drying this area more quickly.

Inside the solar module 100, a filler 122, also called encapsulant, bonds all parts in the solar module 100 and the planar elements 120, 130 together. The encapsulant 122 does not have to enclose all parts without creating air bubbles. Due to the extra-low voltage, air bubbles cannot generate electric arcs and can therefore be accepted in the manufacture of the solar module 100.

The figure shows only one example. The module need not have a seal body 170 or a spiky metal part 340. Electrical and mechanical fixation of a contacting portion 141 may be provided by one or more connecting elements 165. For reference purposes, only one connecting element 165 is shown.

It should be noted that the features of the invention described with reference to individual embodiments or variants, such as the type and design of the individual components and their precise dimensioning and spatial arrangement, may also be present in other embodiments, except where otherwise indicated or where this is self-evident for technical reasons. Moreover, of such features of individual embodiments described in combination, not all features necessarily have to be realized in a respective embodiment.

1. A solar module which is operable in an extra-low voltage range below 60V, the solar module having at least one photovoltaic cell for converting radiant energy into electrical energy and two planar elements made of plastic, which surround the at least one photovoltaic cell in a sandwich-like manner, the solar module having at least one positive contact element and at least one negative contact element for tapping an electrical output voltage of the solar module, the positive contact element and the negative contact element being arranged at least partially between the two planar elements and each having at least one electrically uninsulated exposed contacting portion, wherein an output voltage limiter is associated with the solar module, wherein the output voltage limiter is adapted to limit the output voltage to an extra-low voltage below 60V and/or wherein the number of photovoltaic cells is selected in such a way that the output voltage remains in the extra-low voltage range below 60V.

2. (canceled)

3. The solar module according to claim 1, wherein the output voltage limiter is part of a protection circuit, the protection circuit preferably further comprising a reverse polarity protection and/or an overload fuse as components, wherein at least one of the components of the protection circuit is connected to at least one of the contact elements.

4-5. (canceled)

6. The solar module according to claim 1, wherein an area between the two planar elements is filled with a filler.

7. (canceled)

8. The solar module according to claim 1, wherein at least one of the contacting portions, in addition to electrical contacting during tapping of the output voltage, is also adapted for mechanical contacting of the solar module, so that the solar module is configured to be mechanically arranged on a bearing structure via the at least one contacting portion.

9-11. (canceled)

12. The solar module according to claim 1, wherein the positive contact element and the negative contact element are arranged within an area of the two planar elements and the solar module can be contacted via at least one bore passing through the solar module.

13-15. (canceled)

16. The solar module according to claim 1, wherein the at least one photovoltaic cell comprises an edge protection which embraces the photovoltaic cell at its edges.

17. The solar module according to claim 1, wherein the two planar elements are symmetrical at least in a portion in which the at least one photovoltaic cell is arranged.

18. The solar module according to claim 1, wherein the two planar elements are completely symmetrical.

19. The solar module according to claim 1, wherein the solar module comprises a plurality of wind release openings, which together define a wind permeable area within an area of the solar module, wherein the wind permeable area represents 1% to 60% of the area of the solar module.

20. (canceled)

21. The solar module according to claim 1, wherein the solar module comprises at least one wave-like reinforcing portion, in which at least the two planar elements are wave-like and/or wherein the solar module comprises an embedded reinforcing mesh.

22. The solar module according to claim 1, wherein the two planar elements each comprise a thickness of at most 2.5 mm.

23-25. (canceled)

26. A solar module system comprising:
a plurality of solar modules connected in parallel according to claim 1; and
a bearing structure electrically interconnecting and supporting the plurality of solar modules.

27. The solar module system according to claim 26, wherein the bearing structure comprises a fully electrically conductive module connection structure which is configured to lead the output voltage of the solar modules and which connects the solar modules.

28. The solar module system according to claim 27, wherein the module connection structure is directly connected to at least one of the contacting portions of the solar modules.

29. The solar module system according to claim 27, wherein the bearing structure comprises a support structure supporting the module connection structure.

30. The solar module system according to claim 29, wherein the support structure is formed from an electrically low-conductive material, and wherein the module connection structure is connected to the support structure without electrical insulation.

31. The solar module system according to claim 29, wherein the support structure comprises at least one pole, wherein the pole is connectable via a rotary joint to a ground on which the solar module system is to be assembled, and wherein the pole is configured to be movable by the rotary joint between an assembly position in which the pole lies flat on the ground and an upright operating position, wherein the support structure (320) comprises rotary joint blocking means (323), by which the rotary joint (322) can be blocked when the pole (321) is in the upright operating position.

32. (canceled)

33. The solar module system according claim 31, wherein the support structure comprises a plurality of poles, the rotary joints of which are aligned in the same direction of action, wherein the poles are arranged in a line in such a way that the poles can be moved together into the upright operating position using a force directed in the direction of action, wherein the bearing structure is formed as a busbar comprising the support structure formed of an electrically low-conductive material and the module connection structure in form of a conductive metal sheet, and wherein the conductive metal sheet is a tape.

34-35. (canceled)

36. The solar module system to claim 26, comprising at least one inverter or an inverter module.

37. The solar module system according to claim 36, wherein the solar module system comprises at least two inverters or at least two inverter modules connected in parallel.
